(19) United States
(12) Patent Application Publication
(10) Pub. No.: US 2017/0255100 A1
(43) Pub. Date: Sep. 7, 2017

(54) DRY FILM STRUCTURE

(71) Applicant: Fujifilm Electronic Materials U.S.A., Inc., North Kingstown, RI (US)

(72) Inventors: Sanjay Malik, Attleboro, MA (US); William A. Reinerth, Riverside, RI (US)

(21) Appl. No.: 15/132,467

(22) Filed: Apr. 19, 2016

Related U.S. Application Data
(60) Provisional application No. 62/301,697, filed on Mar. 1, 2016.

(51) Int. Cl. G03F 7/11; H01L 21/683; G03F 7/16; G03F 7/32; G03F 7/38; H01L 21/027; G03F 7/20

(52) U.S. Cl. CPC G03F 7/11; H01L 21/0274; H01L 21/6835; G03F 7/20; G03F 7/32; G03F 7/38; G03F 7/168; H01L 2221/68363

(57) ABSTRACT

This disclosure relates to a dry film structure that includes a carrier substrate, a protective layer, and a polymeric layer between the carrier substrate and the protective layer. The polymeric layer includes at least one protected polybenzoxazole precursor polymer.

### CROSS-REFERENCE TO RELATED APPLICATION

The present application claims priority to U.S. Provisional Application Ser. No. 62/301,697, filed on Mar. 1, 2016, the contents of which are hereby incorporated by reference in its entirety.

### BACKGROUND OF THE DISCLOSURE

Increasingly, semiconductor devices are being utilized in many new embedded applications including a host of new mobile devices. In order to allow this expansion to continue, the manufacturing costs for these semiconductor devices must be reduced. While multiple pathways are being pursued, switching from wafers to large non-circular panels offers several key cost advantages.

### SUMMARY OF THE DISCLOSURE

Circular substrates, such as silicon wafers, permit coating materials like photoresists to be applied by spin coating. For decades, spin coating has been the preferred method for applying photosensitive materials to semiconductor substrates. Large non-circular panel substrates do not permit the use of spin coating as an application method. These substrates require alternative methods for applying photoresists and other semiconductor coatings. One application method is the use of a dry film structure. A dry film structure usually includes a carrier substrate as a support layer, a polymeric layer and a protective layer. After removing the protective layer, the polymeric layer can be conveniently brought into contact with any substrate. Once applied, the polymeric layer of the dry film is then laminated to the substrate. In the case of a dry film resist (DFR), the polymeric layer is photosensitive and acts as a resist. After lamination, the resist material is patternwise exposed to radiation and developed. In other situations, a non-photosensitive film is desired.

Next generation semiconductor packaging requires DFR materials containing a photosensitive polymeric layer capable of excellent resolution and having chemical stability. Resolution of these photosensitive polymeric layers should allow the printing of fine features (<4 microns) with high aspect ratios (>2:1). In addition, following development, these photosensitive polymeric layers must be stable to strong acids and bases used in subsequent processing steps. The dry film structure of this disclosure addresses the needs of advanced packaging applications by providing excellent resolution as well as chemical stability.

In one aspect, this disclosure features a dry film structure that includes a carrier substrate, a protective layer, and a polymeric layer between the carrier substrate and the protective layer. The polymeric layer contains at least one blocked polybenzoxazole precursor polymer.

In another aspect, this disclosure features a process that includes (a) removing the protective layer from the dry film structure described above, and (b) applying the film structure obtained in step (a) onto an electronic substrate to form a laminate.

In still another aspect, this disclosure features a process for construction of a build-up layer stack. The process includes (a) providing a substrate laminated with a dielectric layer; (b) removing the protective layer from the dry film structure described above; (c) applying the structure obtained in step (b) onto the dielectric layer; (d) forming a relief pattern in the polymeric layer, the relief pattern containing open areas; (e) selectively depositing a copper layer in the open areas in the polymeric layer; and (f) removing the polymeric layer.

In still another aspect, this disclosure features an article formed by any of the processes described, in which the article is a semiconductor substrate, a flexible film for electronics, a wire isolation, a wire coating, a wire enamel, or an inked substrate.

In still another aspect, this disclosure features an electronic device that includes the article described above. The electronic device can be an integrated circuit, a light emitting diode, a solar cell, or a transistor.

In yet another aspect, this disclosure features a process of forming a dry film structure. The process includes coating a composition containing at least one blocked polybenzoxazole precursor polymer onto a carrier substrate; drying the coated composition to form a polymeric layer; and applying a protective layer onto the polymeric layer to form the dry film structure.

Some embodiments of the present disclosure describe a dry film structure that contains a polymeric layer prepared from a composition comprising at least one protected (blocked) polybenzoxazole (PBO) precursor and at least one solvent. In some embodiments, the polymeric layer of the dry film structure contains an endcapped protected (blocked) PBO precursor. In some embodiments, the polymeric layer of dry film structure is photosensitive. In some embodiments, the polymeric layer of the dry film structure contains an oxime sulfonate PAG.

Some embodiments of this disclosure concern methods of preparation of a dry film structure containing at least one protected (blocked) PBO precursor, which is optionally made photosensitive (i.e., a dry film resist). Some embodiments of this disclosure concern methods of preparation of a patterned dry film resist containing at least one protected (blocked) PBO precursor. Some embodiments of this disclosure concern a method for construction of a build-up layer stack using a dry film resist containing at least one protected (blocked) PBO precursor.

Some embodiments of this disclosure concerns compositions containing 1) at least one blocked polybenzoxazole precursor polymer; 2) at least one oxime compound containing a phenyl ring substituted with an oxime group and a hydroxy group at the o-position relative to the oxime group; 3) at least one photosensitive compound; and 4) at least one solvent.

### DETAILED DESCRIPTION OF THE DISCLOSURE

In the context of this disclosure, lamination is a process for affixing or adhering the polymeric layer of the dry film structure described herein to a surface of a substrate. Pre-lamination is treatment of a substrate prior to lamination. Pre-lamination includes, but is not limited to, rinsing the substrate with a solvent or additive and drying before lamination.

In general, this disclosure relates to a dry film structure that includes a carrier substrate, a protective layer, and a polymeric layer between the carrier substrate and the protective layer. The polymeric layer contains at least one blocked polybenzoxazole precursor polymer. In some embodiments, the polymeric layer is also known as a dry film. After curing at high temperature (e.g. from about 250° C. to about 425° C.), blocked polybenzoxazole precursor polymers convert to polybenzoxazole polymers with superior mechanical, thermal and electrical properties useful for manufacturing semiconductor and other electrical device.

Some embodiments of the present disclosure describe a dry film structure that contains a polymeric layer prepared from a composition (e.g., a chemically amplified photosensitive composition) containing at least one protected (blocked) polybenzoxazole (PBO) precursor and at least one solvent. As used herein, “a protected PBO precursor” and “a blocked PBO precursor” are used interchangeably.

In some embodiments, the protected or blocked polybenzoxazole (PBO) precursor polymer is prepared by reaction of an appropriate organic reagent with a polyhydroxyamide (PHA) polymer to protect or block the hydroxyl groups on the PHA.

PHA polymers can be prepared by combining one or more phenolic diamine(s) with one or more dicarboxylic acids or dicarboxylic acid derivatives in at least one (e.g., two, three, or more) polymerization solvent(s). When dicarboxylic acid derivatives are employed, suitable derivatives include, but are not limited to, dicarboxylic acid halides and dicarboxylic acid esters.

In order to function as PBO precursor polymers, the PHA polymers are generally prepared from aromatic diamines which possess phenolic hydroxyl groups in an ortho orientation to the —NH₂ groups. Examples of suitable phenolic diamines (e.g., bisaminophenols) that can be used to prepare a PHA polymer include, but are not limited to, 2,2-bis(3-amino-4-hydroxyphenyl)-hexafluoropropane (BisAPAF), 2,2-bis(3-amino-4-hydroxyphenyl) propane, 3,3′-dihydroxybenzidine, 4,6-diaminoresorcinol, 3,3′-dihydroxy-4,4′-diaminobiphenyl (HAB), 3,3′-diamino-4,4′-dihydroxydiphenylsulfone, 4,4′-diamino-3,3′-dihydroxydiphenylsulfone, bis(3-amino-4-hydroxyphenyl)methane, 2,2-bis(4-amino-3-hydroxyphenyl)hexafluoropropane, bis(4-amino-3-hydroxyphenyl)methane, 2,2-bis(4-amino-3-hydroxyphenyl)propane, 4,4′-diamino-3,3′-dihydroxybenzophenone, 3,3′-diamino-4,4′-dihydroxybenzophenone, 4,4′-diamino-3,3′-dihydroxydiphenyl ether, 3,3′-diamino-4,4′-dihydroxydiphenyl ether, 1,4-diamino-2,5-dihydroxybenzene, 1,3-diamino-2,4-dihydroxybenzene, 3-amino-4-[(3-amino-2-hydroxy-3,4-dihydropyridin-4-yl)oxy]pyridin-2-ol, and 1,3-diamino-4,6-dihydroxybenzene. These bisaminophenols can be used alone or in a mixture thereof.

In some embodiments, up to about 50% (e.g., up to about 40%, up to about 30%, up to about 20%, up to about 10%, or up to about 5%) of the dihydroxy diamine monomers used to prepare a PHA polymer can be replaced by a diamine without hydroxyl groups. Examples of suitable diamines without hydroxyl groups include, but are not limited to, p-phenylenediamine, m-phenylenediamine, o-phenylenediamine, 3-methyl-1,2-benzene-diamine, 1,5-diaminonaphthalene, 1,2-diaminoethane, 1,3-diaminopropane, 1,4-diamino-butane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfones, 4,4′-isopropylidenedianiline, 4,4′-diaminodiphenylmethane, 2,2-bis(4-aminophenyl)propane, 4,4′ diaminodiphenyl propane, 4,4′-diaminodiphenylsulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 2,2′-bis (trifluoromethyl) benzidine, 3,3′-bis (trifluoromethyl) benzidine, 2,2-bis [4-(4-aminophenoxy phenyl)] hexafluoropropane, 2,2-bis (3-amino-4-methylphenyl)-hexafluoropropane, 2,2-bis(3-aminophenyl)-1,1,1,3,3,3-hexafluoropropane, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline)isopropylidene, N,N-bis(4-aminophenyl)aniline, bis(p-beta-amino-t-butylphenyl)ether, p-bis-2-(2-methyl-4-aminopentyl)benzene, p-bis(1,1-dimethyl-5-aminopentyl)benzene, 3,3′-dimethyl-4,4′-diaminobiphenyl, 3,3′-dimethoxybenzidine, 4,4′-diaminobenzophenone, 3′-dichlorobenzidine, 2,2-bis [4-(4-aminophenoxy)phenyl] propane, 4,4′[1,3-phenylenebis(1-methyl-ethylidene)] bisaniline, 4,4′-[1,4-phenylenebis(1-methyl-ethylidene)]bisaniline, 2,2-bis [4-(4-aminophenoxy) phenyl] sulfone, 2,2-bis [4-(3-aminophenoxy) benzene], 1,4-bis (4-aminophenoxy) benzene, 1,3-bis (4-aminophenoxy) benzene, 1,3′-bis (3-aminophenoxy) benzene, 2,6-diamino-9H-thioxanthen-9-one, 2,6-diaminoanthracene-9,10-dione, 9H-fluorene-2,6-diamine m-phenylenediamine, 1,5-diaminonaphthalene, 2,5-diaminobenzotrifluoride, 3,5-diaminobenzotrifluoride, 4,4′-oxydianiline, 4,4′-diaminodiphenylsulfones, 2,2-bis(4-aminophenyl)propane, and 4-aminophenyl-3-aminobenzoate.

The dicarboxylic acids or dicarboxylic acid derivatives which are employed can be either aliphatic or aromatic. Examples of suitable dicarboxylic acids that can be used to prepare a PHA polymer include, but are not limited to, malonic acid, methylmalonic acid, dimethylmalonic acid, butylmalonic acid, succinic acid, glutaric acid, 2,2-dimethylglutaric acid, adipic acid, sebacic acid, itaconic acid, maleic acid, difluoromaleic acid, diglycolic acid, 1,1-cyclobutanedicarboxylic acid, 1,2-cyclopentanedicarboxylic acid, 3,3-tetramethyleneglutaric acid, camphoric acid, 1,2-cyclohexanedicarboxylic acid, 1,3-cyclohexanedicarboxylic acid, 1,4-cyclohexanedicarboxylic acid, 1,3-adamantanedicarboxylic acid, 5-norbornene-2,3-dicarboxylic acid, 1,2-phenylenediacetic acid, 1,3-phenylenediacetic acid, 1,4-phenylenediacetic acid, perfluorosuberic acid, phthalic acid, 3-fluorophthalic acid, 4-fluorophthalic acid, 3,4,5,6-tetrafluorophthalic acid, isophthalic acid, 2-fluoroisophthalic acid, 4-fluoroisophthalic acid, 5-fluoroisophthalic acid, 2,4,5,6-tetrafluoroisophthalic acid, terephthalic acid, 2,2-bis(4-carboxyphenyl)propane, 2,2-bis(4-carboxyphenyl)hexafluoropropane, 4,4′-dicarboxydiphenyl ether, 4,4′-dicarboxydiphenyl sulfone, 4,4′-dicarboxydiphenyl thioether, 4,4′-dicarboxybenzophenone, 2,2′-bis(trifluoromethyl)-4,4′-biphenyldicarboxylic acid, 5-nitroisophthalic acid, 1,4-naphthalenedicarboxylic acid, 2,6-naphthalenedicarboxylic acid, 4,4′-biphenyldicarboxylic acid, and 2,5-pyridinedicarboxylic acid.

Examples of suitable dicarboxylic acid halides that can be used to prepare a PHA polymer include, but are not limited to, adipoyl chloride, sebacoyl chloride, sebacoyl bromide, itaconyl chloride, 1,3-cyclohexanedicarbonyl chloride, 1,4-cyclohexanedicarbonyl chloride, 5-norbornene-2,3-dicarbonyl bromide, 1,2-phenylenediacetyl chloride, 1,4-phenylenediacetyl chloride, phthaloyl chloride, 3-fluorophthaloyl bromide, 4-fluorophthaloyl chloride, 3,4,5,6-tetrafluorophthaloyl chloride, isophthaloyl chloride, terephthaloyl chloride, 4,4′-propane-2,2-diyldibenzoyl chloride, 4,4′-hexafluoropropane-2,2-diyldibenzoyl chloride, 4,4′-oxydibenzoyl chloride, 4,4′-thiodibenzoyl chloride, 4,4′-sulfonyldibenzoyl chloride, 4,4′-carbonyldibenzoyl chloride, 2,2′-bis(trifluoromethyl)-4,4′-biphenyldicarbonyl bromide, 5-nitroisophthaloyl chloride, 1,4-naphthalenedicarbonyl bromide, 2,6-naphthalenedicarbonyl chloride and 4,4′-biphenyldicarbonyl chloride.

Examples of suitable dicarboxylic acid esters that can be used to prepare a PHA polymer include, but are not limited to, dimethyl adipate, dimethyl sebacate, diethyl itaconate, dimethyl maleate, diethyl difluoromaleate, diglycolic acid, dimethyl cyclohexane-1,3-dicarboxylate, dimethyl cyclohexane-1,4-dicarboxylate, dimethyl-5-norbornene-2,3-dicarboxylate, dimethyl-1,2-phenylenediacetate, dimethyl-1,4-phenylenediacetate, dimethyl phthalate, diethyl phthalate, dimethyl-3-fluorophthalate, dimethyl-4-fluorophthalate, diethyl-3,4,5,6-tetrafluorophthalate, dimethyl isophthalate, dimethyl-2-fluoroisophthalate, dimethyl-4-fluoroisophthalate, diethyl-2,4,5,6-tetrafluoroisophthalate, dimethyl terephthalate, diethyl 4,4′-propane-2,2-diyldibenzoate, dimethyl 4,4′-hexafluoropropane-2,2-diyldibenzoate, dimethyl 4,4′-carbonyldibenzoate, dimethyl 4,4′-oxydibenzoate, dimethyl biphenyl-3,3′-dicarboxylate, diethyl biphenyl-4,4′-dicarboxylate, dimethyl 4,4′-thiodibenzoate, diethyl 4,4′-sulphonyldibenzoate, dimethyl-1,4-naphthalenedicarboxylate, 2,6-naphthalenedicarboxylate and dimethyl-4,4′-biphenyldicarboxylate.

Any conventional method for reacting a dicarboxylic acid or its dichloride or diester derivative with at least one aromatic diamine (e.g., at least one dihydroxydiamine and optionally at least one diamine without a hydroxyl group) can be used to prepare a PHA polymer. Generally, the reaction can be carried out at about −10° C. to about 30° C. for about 6 hours to about 48 hours in the presence of an approximately stoichiometric amount of a non-nucleophilic amine base. In some embodiments, the diamine(s) can be employed in excess. In such embodiments, the ratio of the diamine to dicarboxylic acid or its derivatives can range from 1.01/1 to 1.25/1. In some embodiments, the dicarboxylic acid(s) or its derivative(s) can be employed in excess. In such embodiments, the ratio of the dicarboxylic acid(s) or its derivative(s) to the diamine can range from 1.01/1 to 1.25/1.

The polymerization solvent(s) for preparation of PHA is generally one or a combination of two or more polar, aprotic solvents. Suitable polar, aprotic solvents include, but are not limited to, dimethylformamide (DMF), dimethylacetamide (DMAc), N-formylmorpholine (NFM), N-methylpyrrolidinone (NMP), N-ethylpyrrolidinone (NEP), dimethylsulfoxide (DMSO), gamma-butyrolactone (GBL), hexamethyl phosphoric acid triamide (HMPT), tetrahydrofuran (THF), methyltetrahydrofuran, 1,4-dioxane and mixtures thereof.

Syntheses of PHA polymers are disclosed in, e.g., U.S. Pat. No. 4,339,521, U.S. Pat. No. 4,395,482, U.S. Pat. No. 4,622,285, U.S. Pat. No. 4,849,051 and U.S. Pat. No. 5,096,999, which are hereby incorporated by reference.

Polybenzoxazole precursors can also be prepared by reacting at least one dicarboxylic acid or at least one dicarboxylic acid ester with at least one bis-o-aminophenol in a suitable solvent in the presence of an activating agent as described in U.S. Pat. No. 5,883,221, which is hereby incorporated by reference.

In embodiments when dicarboxylic acid or its derivatives is used in excess to prepare a PBO precursor polymer, the PBO precursor polymer thus obtained can have Structure (I-a):

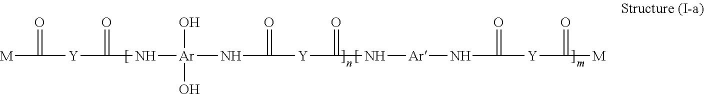

wherein n is an integer from 2 (e.g., 3, 4, or 5) to 1000 (e.g., 750, 500, 250, or 100); m is an integer from 0 (e.g., 1, 3, or 5) to 500 (e.g., 250, 100, 50, or 25); Ar is a tetravalent aromatic group, a tetravalent heterocyclic group, or a mixture thereof; Ar′ is a divalent aromatic group, a divalent aliphatic group, a divalent alicyclic group, a divalent heterocyclic group, or a mixture thereof; Y is a divalent aromatic group, a divalent aliphatic group, a divalent heterocyclic group, a divalent alicyclic group, or a mixture thereof; and M is halogen or an —OR group wherein R is H or C₁-C₄ linear or branched alkyl group. As used herein, the term “heterocyclic group” includes both aromatic and non-aromatic heterocyclic groups.

In some embodiments, Ar is a tetravalent aromatic group or a tetravalent heterocyclic group, or mixtures thereof. Examples of Ar include, but are not limited to:

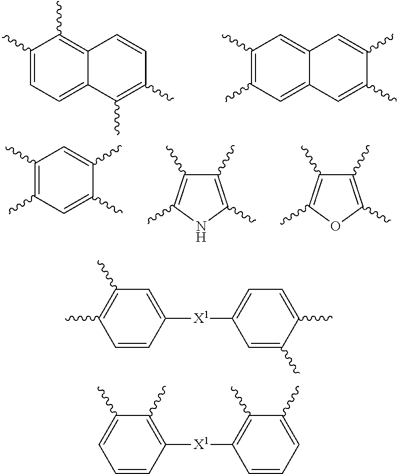

wherein X¹ is —O—, —S—, —C(CF₃)₂—, —C(CH₃)₂—, —CH₂—, —SO₂—, —NHCO— or —SiR¹³₂— and each R¹³ is independently a C₁-C₇ linear or branched alkyl or C₅-C₈ cycloalkyl group. Examples of R¹³ include, but are not limited to, —CH₃, —C₂H₅, n-C₃H₇, i-C₃H₇, n-C₄H₉, t-C₄H₉, and cyclohexyl. In some embodiments, Ar can include a mixture of two or more exemplary groups described above.

In some embodiments, Ar′ is a divalent aromatic, a divalent heterocyclic, a divalent alicyclic, or a divalent aliphatic group that may contain silicon. Examples of Ar′ include, but are not limited to,

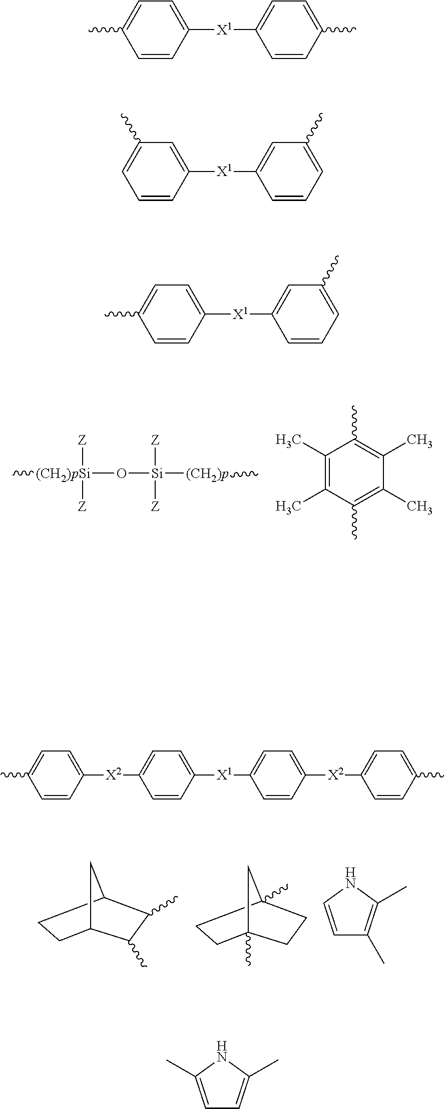

wherein X¹ is as previously defined; X² is —O—, —S—, —C(CF₃)₂—, —C(CH₃)₂—, —CH₂—, —SO₂—, or —NHCO—; and Z is H or C₁-C₈ linear, branched or cyclic alkyl and p is an integer from 1 to 6. Examples of suitable Z groups include, but are not limited to, methyl, ethyl, propyl, isopropyl, n-butyl, sec-butyl, t-butyl, n-octyl, cyclopentyl, cyclohexyl and cyclooctyl.

Examples of Y include, but are not limited to:

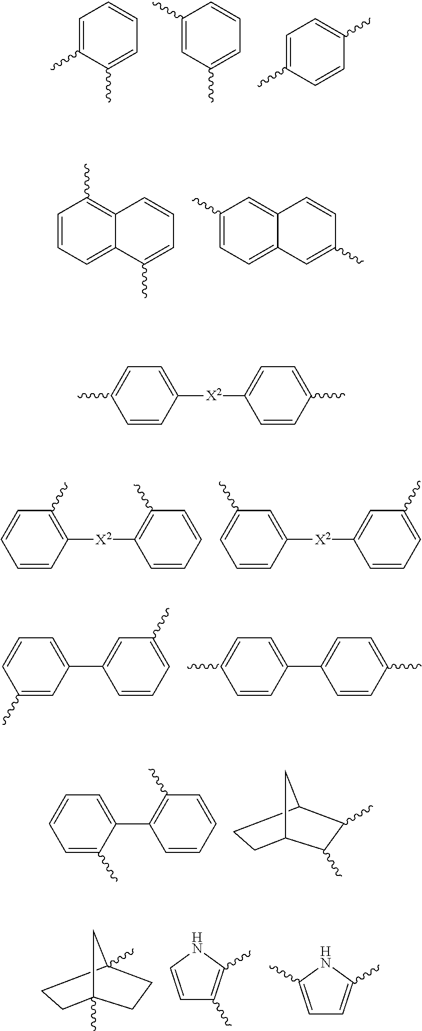

wherein X² is as previously defined.

In embodiments when the diamine is used in excess to prepare a PBO precursor polymer, the PBO precursor polymer can have Structure (I-b):

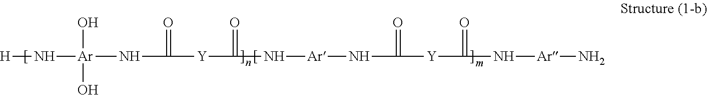

wherein n, m, Ar, Ar′, and Y are as previously defined.

In some embodiments, the PBO precursor polymers are end-capped by reaction with an organic moiety. The terminal group of the polymer is determined by which of the monomer types is used in excess. The reactive groups on the organic moiety for end-capping (on the end-capping reagent) are selected based on the terminal groups of the polymer chain. The end-capping group is preferred to have at least one carbon-carbon multiple bond. Examples of such end capped groups are shown in U.S. Pat. No. 6,607,865 and U.S. Pat. No. 7,687,208 which are hereby incorporated by reference.

In embodiments when dicarboxylic acid or its derivatives is used in excess to prepare an end-capped PBO precursor polymer, the end-capped PBO precursor polymer can have Structure (II-a):

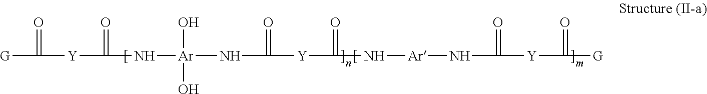

wherein n, m, Ar, Ar′, and Y are as previously defined and G is a monovalent moiety containing at least one carbon-carbon multiple bond.

In embodiments when dicarboxylic acid or its derivatives is used in excess to prepare an end-capped PBO precursor polymer, a compound having an amino group or a hydroxy group is preferably employed as end-capping reagent. Examples of such end-capping reagents include, 4-ethynylaniline, 5-norbornene-2-methylamine, propargylamine, propargyl alcohol, hydroxyethyl methacrylate, and hydroxyethyl acrylate.

In some embodiments, G has the following structures:

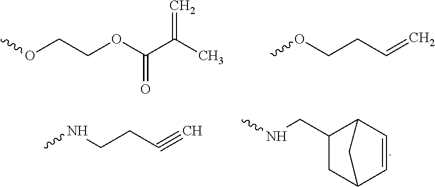

In embodiments when a diamine is used in excess to prepare an end-capped PBO precursor polymer, the end-capped PBO precursor polymer can have Structure (II-b) or (II-c):

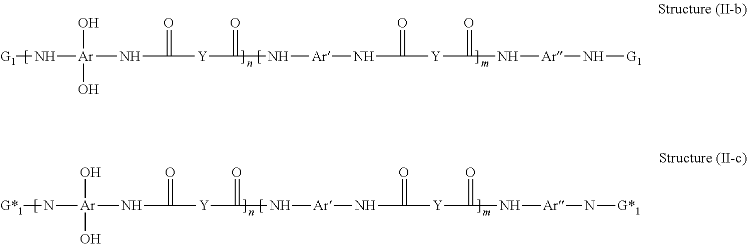

wherein n, m, Ar, Ar′, and Y are as previously defined, Ar″ is Ar(OH)₂ or Ar′; G₁ is a monovalent moiety containing at least one carbon-carbon multiple bond and G*₁ is a divalent moiety containing at least one carbon-carbon multiple bond.

In embodiments when a diamine is used in excess to prepare an end-capped PBO precursor polymer, an acid anhydride, carboxylic acid, acid chloride or compound having an isocyanate group is preferably employed as the end-capping reagent. Examples of such end-capping reagents include benzoyl chloride, norbornenedicarboxylic anhydride, norbornenecarboxylic acid, methyl-5-norbornene-2,3-dicarboxylic dianhydride, ethynylphthalic anhydride, maleic anhydride, cyclohexenedicarboxylic anhydride, methacryloyloxyethyl methacrylate, 2-isocyanatoethyl methacrylate, and 4-methacryloxyethyl trimellitic anhydride.

In some embodiments, G₁ can have the following structures:

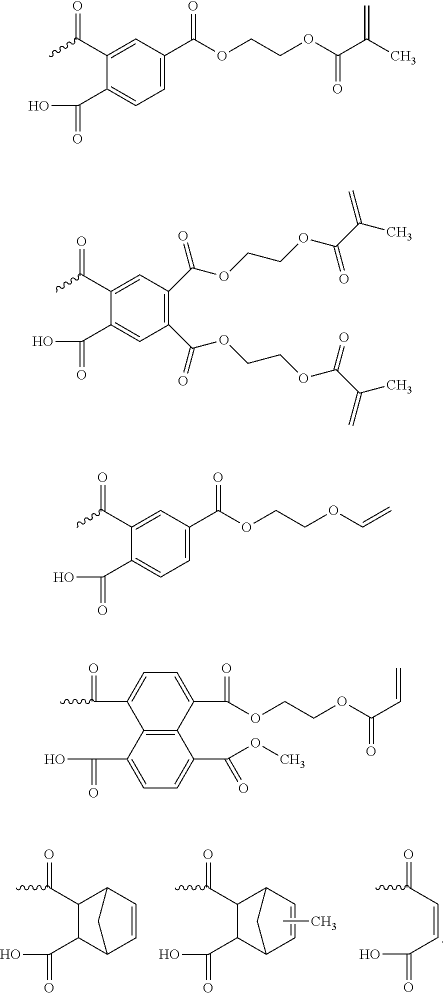

In some embodiments, G*₁ can have the following structures:

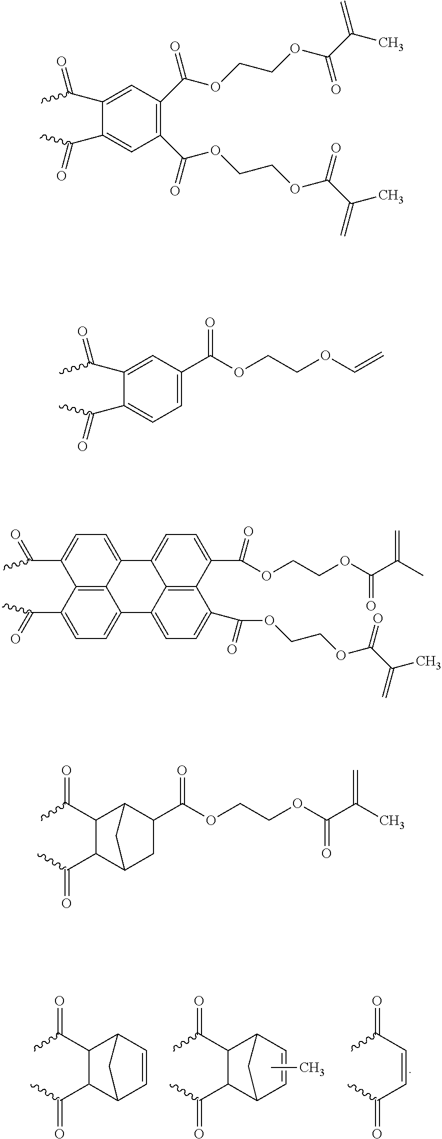

In some embodiments, at least some (e.g., all) the phenolic hydroxyl groups on PHA polymers are blocked by reaction with an organic moiety. In such embodiments, the PHA polymers can possess a combination of both unblocked and blocked phenolic hydroxyl groups. Exemplary syntheses of such PHA polymers are disclosed in, e.g., U.S. Pat. No. 4,339,521, U.S. Pat. No. 4,622,285 and U.S. Pat. No. 4,845,183, which are hereby incorporated by reference.

In some embodiment, the blocked PHA polymers have the structure (III-a) or (III-b):

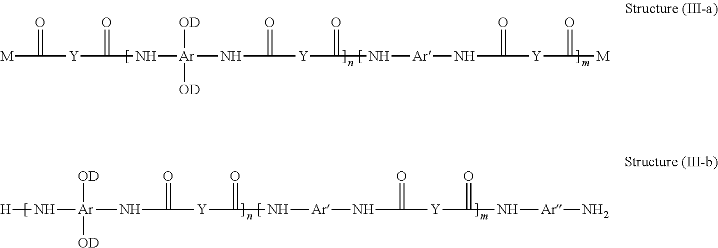

wherein n, m, Ar, Ar′, Y and M are as previously defined, Ar″ is Ar(OD)₂ or Ar′ and each D, independently, is a hydrogen atom or an acid removable blocking group (E).

In some embodiments, the PHA polymers are both endcapped and have at least partial blocking of the phenolic hydroxyl groups.

In some embodiments, the structure of the PHA polymers that are both endcapped and have at least partial blocking of the phenolic hydroxyl group are those of Structure (IV-a), (IV-b) or (IV-c):

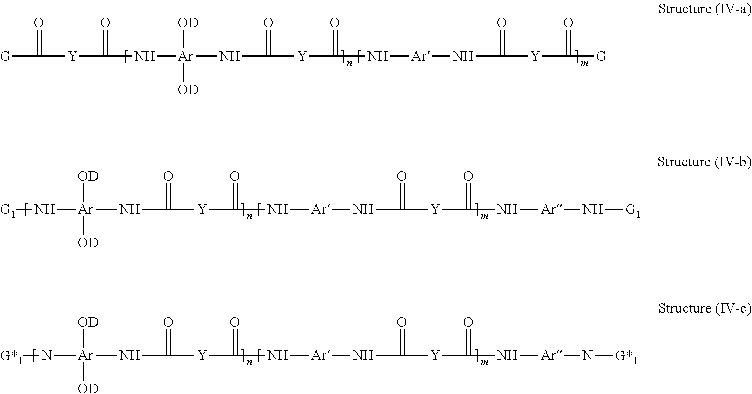

wherein n, m, Ar, Ar′, Ar″, Y, D, G, G₁, and G*₁ are as previously defined.

In some embodiments, the organic moiety used to block the phenolic hydroxyl groups of PHA polymers (i.e., group D in Structures (III-a) to Structure (IV-c) above) is an acid removable blocking group E which is sensitive to the action of an acid (i.e., an acid-sensitive or acid-removable group that can be cleaved or removed in the presence of an acid). Examples of suitable acid sensitive groups include, but are not limited to, acetals, ketals, alkoxy ethers, silyl ethers, tertiary esters, and mixtures thereof. Suitable acid sensitive groups are well known to those skilled in the art.

In some embodiments, the protected or blocked polybenzoxazole precursor polymer is a polymer of Structure (III-a), (III-b), (IV-a), (IV-b), or (IV-c).

Exemplary methods to synthesize PBO precursor polymers described above are disclosed in, e.g., U.S. Pat. No. 6,143,467 and U.S. Pat. No. 7,132,205, which are hereby incorporated by reference. In these embodiments, the ratio of blocked phenolic hydroxyl groups to the total number of phenolic hydroxyl groups can range from about 1 mole % to about 99 mole %. A preferred ratio of blocked phenolic hydroxyl groups to the total number of phenolic hydroxyl groups is from about 10 mole % (e.g., about 12.5 mole %, about 15 mole %, about 20 mole %, or about 25 mole %) to about 50 mole % (e.g., about 45 mole %, about 40 mole %, about 35 mole %, or about 30 mole %).

Suitable solvents for the compositions to prepare the polymeric layer of the dry film structure include polar organic solvents. Suitable examples of polar organic solvents include, but are not limited to, N-methylpyrrolidone (NMP), N-ethylpyrrolidone (NEP), N-butylpyrrolidone (NBP), N-formylmorpholine (NFM), gamma-butyrolactone (GBL), N,N-dimethylacetamide (DMAc), dimethyl-2-piperidone, N,N-dimethylformamide (DMF), propylene glycol monomethyl ether acetate (PGMEA), propylene glycol monomethyl ether (PGME), ethyl lactate and mixtures thereof. In some embodiments, the solvents are gamma-butyrolactone, ethyl lactate, propylene glycol monomethyl ether acetate, propylene glycol monomethyl ether, and mixtures thereof. In some embodiments, solvents are gamma-butyrolactone, propylene glycol monomethyl ether acetate, propylene glycol monomethyl ether, and mixtures thereof.

Some embodiments of the present disclosure describe a photosensitive dry film structure containing a polymeric layer prepared from a composition (e.g., a chemically amplified photosensitive composition) containing at least one protected or blocked polybenzoxazole (PBO) precursor, at least one compound which generates acid upon exposure to light or radiation (i.e., a photoacid generator or a PAG), and at least one solvent.

In some embodiments, PAGs used in the present disclosure are active to the radiation between about 300 nm to about 460 nm. Preferred PAGs form a homogeneous solution in the photosensitive composition and produce strong acid (pKa<1) upon irradiation. Examples of such acids include hydrogen halides, sulfonic acids, or perfluoroalkylcarboxylic acids such as trifluoroacetic acid. The classes of such PAGs include, but are not limited to, oxime sulfonates, triazines, or sulfonium or iodonium salts of sulfonic acids. Examples of suitable PAGs also include those that have an anion containing a tris-(highly fluorinated alkylsulfonyl)methide, a tris-(fluorinated arylsulfonyl)methide, a bis-(highly fluorinated alkylsulfonyl)imide, a bis-(fluorinated arylsulfonyl) imide, a mixed aryl- and alkylsulfonyl imide and a mixed aryl- and alkylsulfonyl methide. Such PAGs are disclosed, e.g., in U.S. Pat. No. 5,554,664, the contents of which are hereby incorporated by reference. Other examples of suitable PAGs are those disclosed, e.g., in U.S. Pat. No. 6,143,467, U.S. Pat. No. 7,132,205, U.S. Pat. No. 7,923,196, U.S. Pat. No. 8,039,200 and U.S. Pat. No. 8,426,103, the contents of which are hereby incorporated by reference. Mixtures of suitable PAGs of the same or different types and classes can be employed.

In some embodiments, a photoacid generator can be a diazonaphthoquinone compound, which can be the condensation product of compounds containing from about two to about nine aromatic hydroxyl groups with a 5-naphthoquinone diazide sulfonyl compound and/or a 4-naphthoquinone diazide sulfonyl compound. Examples of such diazonaphthoquinone compounds include, but are not limited to, those that are disclosed in, e.g., U.S. Pat. No. 2,772,972, U.S. Pat. No. 279,213, U.S. Pat. No. 3,669,658, US544958, U.S. Pat. No. 6,235,436, U.S. Pat. No. 6,607,865, U.S. Pat. No. 6,927,013, U.S. Pat. No. 7,416,830 and U.S. Pat. No. 7,745,516, the contents of which are hereby incorporated by reference. In some embodiments, the composition used to prepare a polymeric layer of the dry film structure described herein excludes any diazonaphthoquinone compounds.

In some embodiments, the PAG is an oxime sulfonate of Structure (V) or Structure (VI), wherein R⁶ is selected from the group consisting of substituted or unsubstituted C₁-C₁₂ linear or branched alkyl, substituted or unsubstituted C₅-C₁₀ cycloalkyl or heterocycloalkyl, and substituted or unsubstituted C₆-C₁₂ aryl or heteroaryl; each R⁷ is independently selected from the group consisting of hydrogen, halogen, substituted or unsubstituted C₁-C₁₂ linear or branched alkyl, substituted or unsubstituted C₅-C₁₀ cycloalkyl or heterocycloalkyl, and substituted or unsubstituted C₆-C₁₂ aryl or heteroaryl; R⁸ to R¹⁷ are each independently selected from the group consisting of hydrogen, halogen, substituted or unsubstituted C₁-C₁₂ linear or branched alkyl, substituted or unsubstituted C₅-C₁₀ cycloalkyl or heterocycloalkyl, and substituted or unsubstituted C₆-C₁₂ aryl or heteroaryl, or any two adjacent R⁸ to R¹¹, R¹² to R¹³, and R¹⁴ to R¹⁷ (e.g., R⁸ and R⁹, R⁹ and R¹⁰, R¹⁰ and R¹¹, R¹² and R¹³, R¹⁴ and R¹⁵, R¹⁵ and R¹⁶, or R¹⁶ and R¹⁷), together with the ring carbon atoms to which they are attached, form a six-membered ring; and X is an oxygen or sulfur atom.

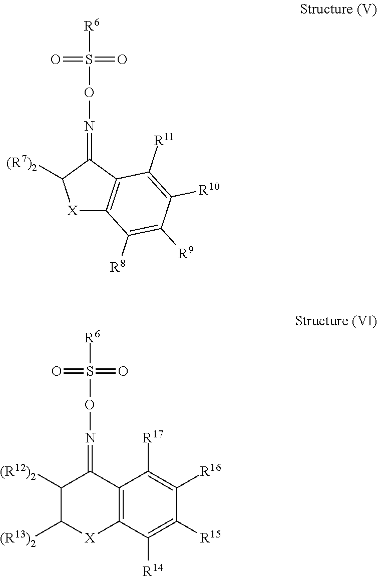

Specific examples of PAGs having Structure (V) are:

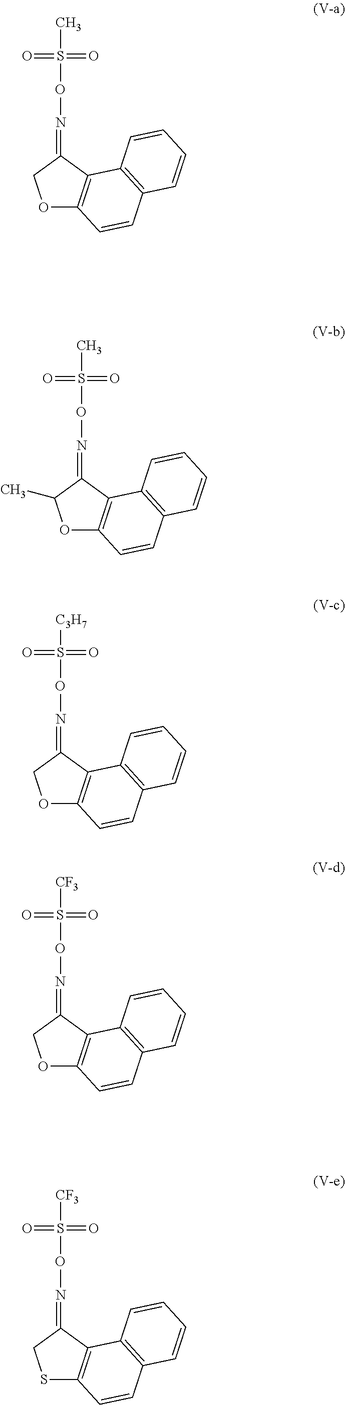

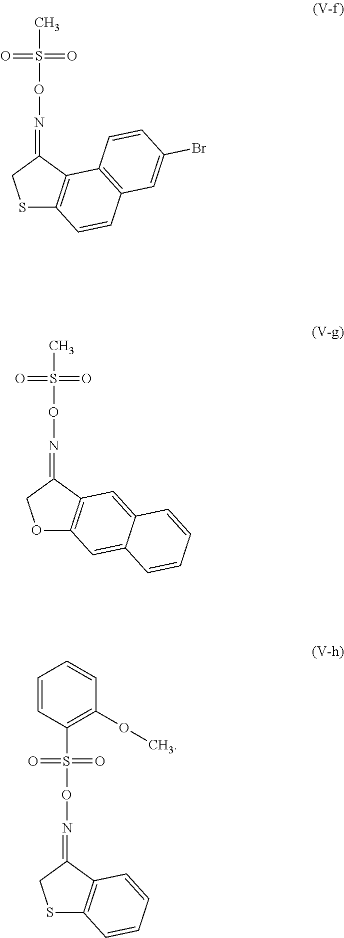 [SMILES: CS(=O)(=O)ON=C1CSc2ccc3cc(Br)ccc3c21 ; CS(=O)(=O)ON=C1COc2cc3ccccc3cc21 ; COc1ccccc1S(=O)(=O)ON=C1CSc2ccccc21]

Specific examples of PAGs having Structure (VI) are:

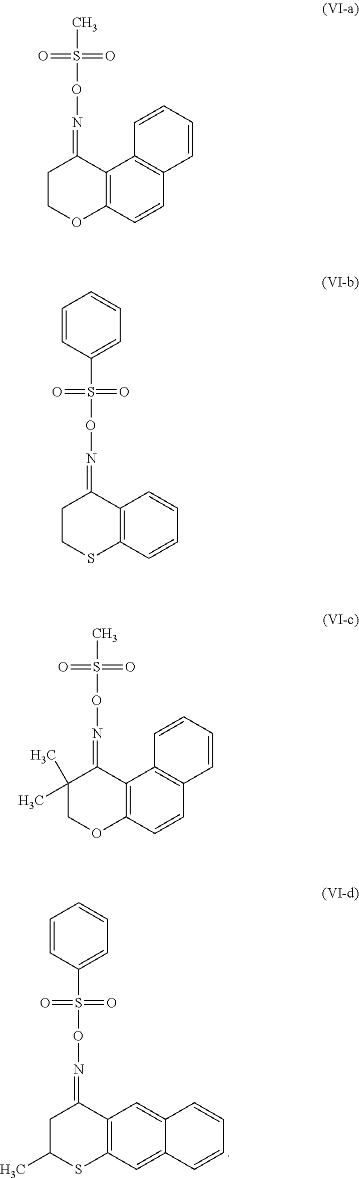 [SMILES: CS(=O)(=O)ON=C1CCOc2ccc3ccccc3c21 ; O=S(=O)(ON=C1CCSc2ccccc21)c1ccccc1 ; CC1(C)COc2ccc3ccccc3c2C1=NOS(C)(=O)=O ; CC1CC(=NOS(=O)(=O)c2ccccc2)c2cc3ccccc3cc2S1]

Some embodiments of the present disclosure describe a photosensitive dry film structure containing a polymeric layer prepared from a composition containing at least one protected or blocked polybenzoxazole (PBO) precursor, at least one PAG, at least one quencher (e.g., a basic component or compound), and at least one solvent.

Without wishing to be bound by theory, it is believed that the presence of quencher in the polymeric layer of the photosensitive dry film can improve resolution and photospeed reproducibility of said photosensitive dry films. Examples of such quenchers are disclosed in US2009197067, U.S. Pat. No. 6,852,466, U.S. Pat. No. 5,580,695, U.S. Pat. No. 7,923,196, U.S. Pat. No. 7,153,630, U.S. Pat. No. 8,349,535, U.S. Pat. No. 7,923,196, U.S. Pat. No. 6,274,286, U.S. Pat. No. 7,084,303, U.S. Pat. No. 6,303,264, U.S. Pat. No. 6,043,003, and U.S. Pat. No. 7,713,677, the content of which are hereby incorporated by reference.

In some embodiments, the quencher is a tertiary amine. Examples of tertiary amines include, but are not limited to, the following structures:

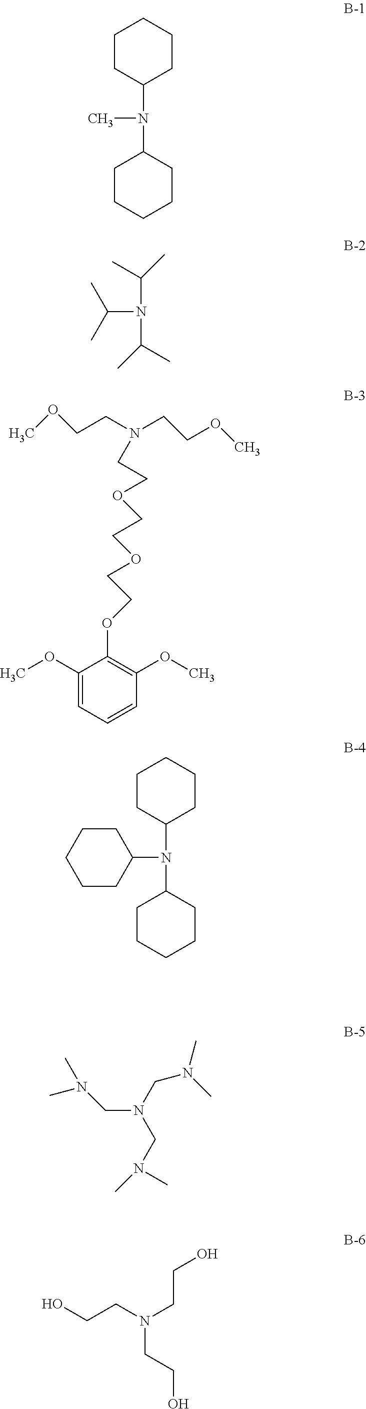

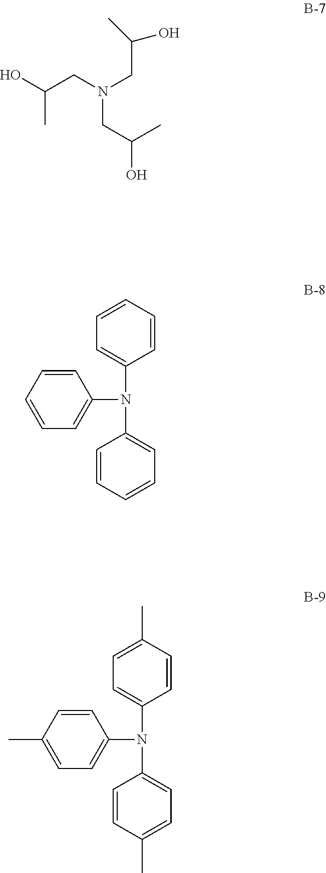 [SMILES: CC(O)CN(CC(C)O)CC(C)O ; c1ccc(N(c2ccccc2)c2ccccc2)cc1 ; Cc1ccc(N(c2ccc(C)cc2)c2ccc(C)cc2)cc1]

In some embodiments, the polymeric layer in the dry film structure can optionally further include other additives such as adhesion promoters, copper compatibilizing additives, leveling agents, dissolution inhibitors, speed enhancers, plasticizers, and the like.

Adhesion promoters that can be used in the polymeric layer described herein include, for example, alkoxysilanes, and mixtures or derivatives thereof. Examples of suitable adhesion promoters are disclosed, e.g., in U.S. Pat. No. 7,132,205, U.S. Pat. No. 7,416,830, U.S. Pat. No. 7,407,731, U.S. Pat. No. 6,939,659 and U.S. Pat. No. 7,056,641, the contents of which are hereby incorporated by reference. Additionally, examples of suitable silane adhesion promoters are commercially available from Gelest Inc. (Morrisville, Pa.).

Certain examples of copper compatibilizing additives that can be used in the polymeric layer described herein are disclosed, e.g., in U.S. Pat. No. 7,407,731, U.S. Pat. No. 7,220,520 and U.S. Pat. No. 8,097,386, the contents of which are hereby incorporated by reference.

In some embodiments, the copper compatibilizing additive is at least one oxime compound containing a phenyl ring substituted with an oxime group and a hydroxy group at the ortho-position relative to the oxime group.

In some embodiments, the copper compatibilizing additive has Structure (VII):

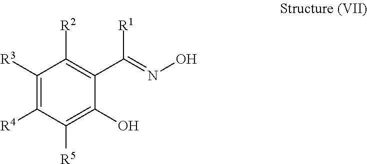

in which R¹ is selected from the group consisting of hydrogen, substituted or unsubstituted C₁-C₁₂ linear or branched alkyl, substituted or unsubstituted C₅-C₁₀ cycloalkyl or heterocycloalkyl, and substituted or unsubstituted C₆-C₁₂ aryl or heteroaryl; and R² to R⁵ are each independently selected from the group consisting of hydrogen, halogen, substituted or unsubstituted C₁-C₁₂ linear or branched alkyl, substituted or unsubstituted C₅-C₁₀ cycloalkyl, and substituted or unsubstituted C₆-C₁₂ aryl; or any two adjacent R² to R⁵ (e.g., R² and R³, R³ and R⁴, or R⁴ and R⁵), together with the ring carbon atoms to which they are attached, form a six-membered ring. Examples of R¹ groups include, but are not limited to, hydrogen, methyl, and phenyl. Examples of R²-R⁵ groups include, but are not limited to, hydrogen, halogen, nonyl, dodecyl, phenyl, iso-propyl, t-butyl, cyclopentyl, 1,3-dimethylcyclohexyl, and tolyl.

Examples of suitable compounds of Structure (VII) include, but are not limited to,

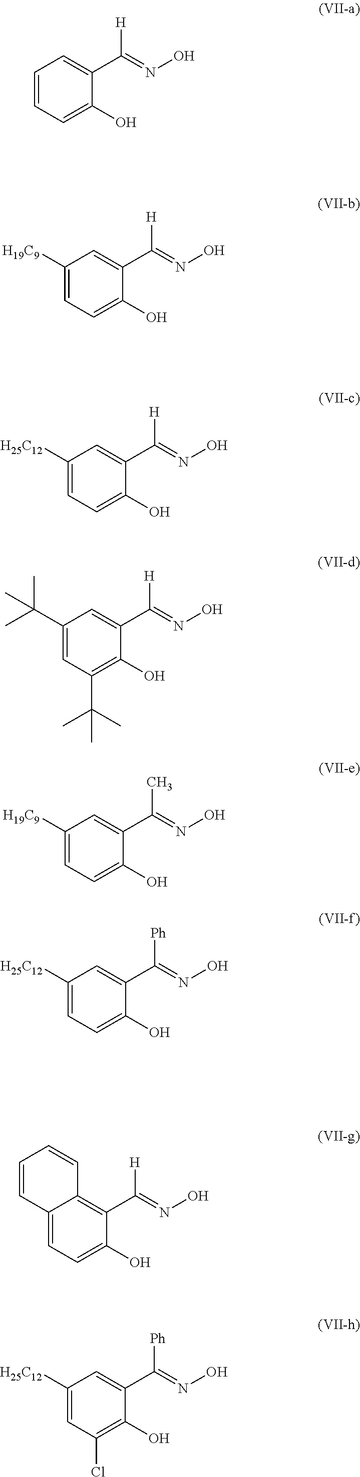

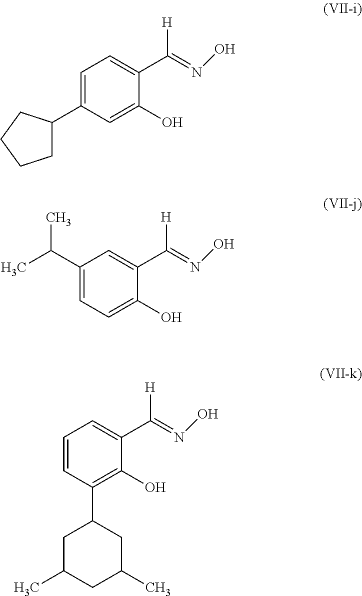 [SMILES: O/N=C/c1ccc(C2CCCC2)cc1O ; CC(C)c1ccc(O)c(/C=N/O)c1 ; CC1CC(C)CC(c2cccc(/C=N/O)c2O)C1]

In some embodiments, the polymeric layer in the dry film structure described herein can further include at least one nanoparticle (e.g., a plurality of nanoparticles). The nanoparticle can be made from one or more polymers, inorganic materials, and/or metals.

The nanoparticles suitable for this application are preferably less than 200 μm in diameter and are compatible with the other components of the compositions of this disclosure. Examples of such nanoparticles are found, e.g., in U.S. Pat. Nos. 6,291,070 and 6,844,950, the contents of which are hereby incorporated by reference.

Examples of nanoparticles include surface treated or untreated silica, alumina, titania, zirconia, hafnium oxide, CdSe, CdS, CdTe, CuO, zinc oxide, lanthanum oxide, niobium oxide, tungsten oxide, strontium oxide, calcium titanium oxide, sodium titanate, and potassium niobate.

In some embodiments, the compositions for preparation of the polymeric layer of the dry film structure of this disclosure include at least about 40% by weight (e.g., at least about 45% by weight, at least about 50% by weight, or at least about 55% by weight) and/or at most about 95% by weight (e.g., at most about 90% by weight, at most about 75% by weight, or at most about 60% by weight) of at least one solvent.

In some embodiments, the compositions for preparation of the polymeric layer of the dry film structure of this disclosure include at least about 5% by weight (e.g., at least about 8% by weight, at least about 10% by weight, or at least about 15% by weight) and/or at most about 45% by weight (e.g., at most about 35% by weight, at most about 25% by weight, or at most about 20% by weight) of at least one protected or blocked polybenzoxazole precursor polymer.

In some embodiments, the compositions for preparation of the polymeric layer of the dry film structure of this disclosure include at least about 0.25% by weight (e.g., at least about 0.4% by weight, at least about 0.5% by weight, or at least about 0.75% by weight) and/or at most about 3% by weight (e.g., at most about 1.5% by weight, at most about 1.2% by weight, or at most about 1% by weight) of at least one PAG.

In some embodiments, the compositions for preparation of the polymeric layer of the dry film structure of this disclosure include at least about 0.01% by weight (e.g., at least about 0.02% by weight, at least about 0.05% by weight, or at least about 0.1% by weight) and/or at most about 0.5% by weight (e.g., at most about 0.4% by weight, at most about 0.3% by weight, or at most about 0.2% by weight) of at least one quencher.

In some embodiments, the compositions for preparation of the polymeric layer of the dry film structure of this disclosure include at least about 0.3% by weight (e.g., at least about 0.5% by weight, at least about 0.75% by weight, or at least about 1% by weight) and/or at most about 4% by weight (e.g., at most about 3% by weight, at most about 2% by weight, or at most about 1.5% by weight) of at least one copper compatibilizing additive.

In some embodiments, the compositions for preparation of the polymeric layer of the dry film structure of this disclosure include at least about 0.3% by weight (e.g., at least about 0.5% by weight, at least about 0.75% by weight, or at least about 1% by weight) and/or at most about 4% by weight (e.g., at most about 3% by weight, at most about 2% by weight, or at most about 1.5% by weight) of at least one adhesion promoter.

In some embodiments, the compositions for preparation of the polymeric layer of the dry film structure of this disclosure include at least about 0.6% by weight (e.g., at least about 1% by weight, at least about 1.5% by weight, or at least about 2% by weight) and/or at most about 8% by weight (e.g., at most about 6% by weight, at most about 4% by weight, or at most about 3% by weight) of at least one plasticizer.

In some embodiments, the compositions for preparation of the polymeric layer of the dry film structure of this disclosure include at least about 0.6% by weight (e.g., at least about 1% by weight, at least about 1.5% by weight, or at least about 2% by weight) and/or at most about 8% by weight (e.g., at most about 6% by weight, at most about 4% by weight, or at most about 3% by weight) of at least one speed enhancer.

In some embodiments, the compositions for preparation of the polymeric layer of the dry film structure of this disclosure include at least about 5% by weight (e.g., at least about 10% by weight, at least about 15% by weight, or at least about 20% by weight) and/or at most about 40% by weight (e.g., at most about 35% by weight, at most about 30% by weight, or at most about 25% by weight) of at least one nanoparticle.

In some embodiments, to prepare a dry film structure, a polymeric layer solution is prepared by mixing at least one suitable solvent, at least one protected or blocked PBO precursor polymer, at least one PAG (optional), at least one quencher (optional), at least one copper compatibilizing additive (optional), at least one adhesion promoter (optional) and at least one nanoparticle (optional), until a uniform solution is obtained. Optionally, other components such as speed enhancers, plasticizers, leveling agents, dyes, etc. can also be added to prepare the polymeric layer solution.

In some embodiments, the polymeric layer solution used for preparation of a dry film structure of this disclosure can be filtered using a filtration media before it is coated onto a carrier substrate.

In some embodiment, the filtration process is completed by using a membrane filter having pore size of 0.2 μm or less. In some embodiments, the material for the membrane filter is preferably polypropylene or Teflon.

In some embodiments, a hollow fiber membrane filter can be used to filter the polymeric layer solution. Examples of such hollow fiber membrane filters have been described, e.g., in US 20070254243, the content of which is hereby incorporated by reference.

In some embodiments, this disclosure features methods of preparation of a dry film structure. The method includes: (a) coating a carrier substrate with a composition containing at least one protected (blocked) polybenzoxazole (PBO) precursor, (b) drying the coated composition to form a polymeric layer, and (c) applying a protective layer to the polymeric layer to form a dry film structure. In some embodiments, the polybenzoxazole precursor film is optionally made photosensitive.

Some embodiments of this disclosure describe a process for preparation of a dry film structure from a filtered polymeric layer solution. For example, the filtered polymeric layer solution described earlier can be first coated on a carrier substrate. The carrier substrate typically functions as a mechanical support for the polymeric layer of the dry film structure during manufacturing, storage and subsequent processing.

In some embodiments, the carrier substrate is a single or multiple layer film, which optionally has undergone treatment to modify the surface of the film that will contact the polymeric layer of the dry film structure. In some embodiments, one or more layers of a multilayer carrier substrate can contain particles. Examples of particles include, but not limited to, inorganic particles such as silicon dioxide particles (aggregated silica and the like), calcium carbonate particles, alumina particles, titanium oxide particles, and barium sulfate particles; organic particles such as crosslinked polystyrene particles, acrylic particles, and imide particles; and their mixtures. Without wishing to be bound by theory, it is believed that the particles can improve the adhesion properties of the carrier substrate, and can improve the uniformity of the polymeric layer coated on the carrier substrate.

In some embodiments, the carrier substrate has excellent optical transparency and it is substantially transparent to actinic irradiation used to form a relief pattern in the polymer layer. In some embodiments, the carrier substrate can possess low surface roughness. The carrier substrate in general should be sufficiently strong and should be insoluble in the solvent used to form the polymeric layer.

The carrier substrate can be removed from the remainder of the dry film structure (e.g., the polymeric layer) in subsequent use, or can form part of the final structure of the fabricated device. In situations where the carrier substrate is eventually removed from the final device, such as by peeling, adhesion between the carrier substrate and the polymeric layer should be weak enough to allow for ease of separation. In such embodiments, the carrier substrate can include a release layer on the surface to be coated by the polymeric layer to facilitate removal of the carrier substrate. In cases in which the carrier substrate is part of the final device, adhesion should be high to prevent peeling of the carrier substrate.

As specific examples of the carrier substrate, there may be various plastic films such as those made from polyethylene terephthalate (PET), polyethylene naphthalate, polypropylene, polyethylene, cellulose tri-acetate, cellulose di-acetate, poly(metha)acrylic acid alkyl ester, poly(metha)acrylic acid ester copolymer, polyvinylchloride, polyvinyl alcohol, polycarbonate, polystyrene, cellophane, polyvinyl chloride copolymer, polyamide, polyimide, vinyl chloride-vinyl acetate copolymer, polytetrafluoroethylene, polytrifluoroethylene, and a mixture thereof. In some embodiments, the carrier substrate can be a laminate made from two or more plastic films. Polyethylene terephthalate (PET) film having excellent optical transparency is preferable. In some embodiments, the thickness of the carrier substrate is in the range of at least about 10 μm (e.g., at least about 15 μm, at least about 20 μm, at least about 30 μm, at least about 40 μm, at least about 50 μm, or at least about 60 μm) to at most about 150 μm (e.g., at most about 140 μm, at most about 120 μm, at most about 100 μm, at most about 90 μm, at most about 80 μm, or at most about 70 μm).

The carrier substrate can be used with or without corona treatment. Corona is ionized air created by discharging high frequency high voltage energy across a metal or insulated electrode. This electrode is positioned over a grounded roll. The corona treatment of films can optimize surfaces for adhesion by removing surface contaminants, creating bonding sites and raising the surface energy. In some embodiments, corona treatment can be done during winding of the carrier substrate film to form a roll by passing the film through a corona process. This produces pretreated corona film. Such corona treated carrier substrate films are commercially available. Another option is “online corona treatment” where the carrier substrate film is passed through a corona chamber just before coating of the polymeric layer composition onto the carrier substrate. On line corona treatment of carrier substrates can improve print quality, eliminates pinholing in coating, and increases dry film structure productivity.

The coating method to form the polymeric layer of the dry film structure is not particularly limited. For example, methods such as spray coating, roll coating, rotation coating, slit coating, compression coating, curtain coating, die coating, wire bar coating, and knife coating can be used to form the polymeric layer. The drying temperature used to form the polymeric layer can vary according to the components, the organic solvent, and the content ratio. In some embodiments, drying is carried out at a temperature of at least about 60° C. (e.g., at least about 65° C., at least about 70° C. or at least about 75° C.) to at most about 120° C. (e.g., at most about 105° C., at most about 90° C. or at most about 85° C.) for at least about 30 seconds (e.g., at least about 1 minute, at least about 2 minutes, at least about 4 minutes, or at least about 6 minutes) to at most about 15 minutes (e.g., at most about 12 minutes, at most about 10 minutes, or at most about 8 minutes). An example of the drying means is a convection oven using hot air, but any suitable heating means can be employed.

The thickness of the polymeric layer of the dry film structure of the present disclosure is not particularly limited. The thickness can be at least about 2 μm (e.g., at least about 5 μm, at least about 10 μm, at least about 20 μm, at least about 25 μm, at least about 30 μm, at least about 35 μm or at least about 40 μm) and/or at most about 100 μm (e.g., at most about 90 μm, at most about 80 μm, at most about 70 μm, at most about 60 μm, at most about 50 μm or at most about 45 μm).

In some embodiments, the dry film structure includes a protective layer (e.g., a protective film or a protective cover sheet) so that the polymeric layer is disposed between the protective layer and the carrier substrate. The protective layer can protect the polymeric layer during the transit and storage and keeping the tacky polymeric layer from sticking to itself. In some embodiments, the protective layer is a single or multiple layer film, which optionally has undergone treatment to modify the surface of the film that will contact the polymeric layer of the dry film structure. The protective layer can be made from polyethylene, polypropylene, or any suitable polymer. In some embodiments, adhesion of the protective layer to the polymeric layer is less than that of the carrier substrate to the polymeric layer. This allows for easy separation of the protective layer from the polymeric layer without also separating the polymeric layer from the carrier substrate. The protective layer can be laminated to the polymeric layer by a roll compression method.

In some embodiments, the polymeric layer of the dry film structure can be laminated to any type of substrates (e.g., electronic substrates) using a differential pressure laminator where vacuum, heat, and pressure are combined for voidless lamination. For example, the protective layer of the dry film structure can be peeled off, and the remainder of the structure (i.e., a polymeric layer on a carrier substrate) can then be cut to the substrate size before the polymeric layer is laminated onto the substrate. As another example, the dry film structure can first be cut to the substrate size and then the protective layer can be peeled off to laminate the polymeric layer onto a substrate. In some embodiments, these substrates, pre-laminated either manually or with the assistance of currently available dispensing equipment, are placed on the slide mounted platen or positioned in a chamber. Substrates varying in thickness and geometry can be intermixed to increase throughput. The substrate can then be exposed to a vacuum dwell for a time determined by an integral precision digital timer. Following this period, a preheated silicone rubber diaphragm can descend onto the work piece. This action can close the small gap below the spring-mounted platen assembly and provides direct thermal contact with the lower heat platen. The temperatures of both the upper and lower heated platens can be controlled independently by integral temperature controllers. Differential pressure laminator generally permits the addition of positive pressure above the diaphragm, increasing the effective lamination pressure dramatically. The pressure dwell period can be adjusted with a timer identical to that employed in the vacuum dwell. Upon completion of a cycle, the drawer mechanism can be retracted and the laminated substrate can be removed for further processing.

In some embodiments, the polymeric layer can be laminated to a substrate through a vacuum lamination at 60° C. to 140° C. after pre-laminating of the polymeric layer of the dry film structure with a plane compression method or a hot roll compression method. When the hot roll lamination is employed, the dry film structure can be placed into a hot roll laminator, the protective layer can be peeled away from the polymeric layer/carrier substrate, and the polymeric layer can be brought into contact with and laminated to a substrate using rollers with heat and pressure.

In some embodiments, the lamination temperature used in the lamination process described above is at least about 50° C. (e.g., at least about 70° C., at least about 80° C., at least about 90° C., or at least about 100° C.) to at most about 220° C. (e.g., at most about 190° C., at most about 170° C., at most about 130° C., or at most about 110° C.). The pressure used in the lamination process described above is at least about 1.5 psi (e.g., at least about 3 psi, at least about 5 psi, at least about 10 psi, at least about 15 psi, or at least about 20 psi) to preferably at most about 70 psi (e.g., at most about 60 psi, at most about 50 psi, at most about 40 psi, or at most about 30 psi). The vacuum used in the lamination process described above can be at least about 0.2 torr to at most about 5 torr. The speed of the roller used in the lamination process described above can be at least about 1 cm/min (e.g., at least about 5 cm/min, at least about 10 cm/min, at least about 25 cm/min, or at least about 50 cm/min) to at most about 600 cm/min (e.g., at most about 500 cm/min, at most about 400 cm/min, at most about 300 cm/min at most about 200 cm/min, or at most about 100 cm/min).

In some embodiments, this disclosure features a process of forming a laminate. The process can include (a) removing the protective layer from the dry film structure described herein; and (b) applying the film structure obtained in step (a) onto an electronic substrate to form a laminate. In some embodiments, the process can further include exposing the polymeric layer in the laminate to actinic radiation. In such embodiments, the process can further include removing the carrier substrate before or after exposing the polymeric layer. After the polymeric layer is exposed to actinic radiation, the process can further include developing the exposed polymeric layer to form a relief pattern.

Some embodiments of this disclosure concern a process of preparation of a patterned dry film resist. The process includes:

(a) providing a substrate (e.g., an electronic substrate) laminated with a dielectric layer (e.g., a patterned dielectric layer),

(b) removing the protective layer of a photosensitive dry film structure of this disclosure,

(c) laminating the polymeric layer of the photosensitive dry film structure to the dielectric layer, (d) exposing the polymeric layer of the photosensitive dry film structure with actinic radiation through a mask,

(e) baking the polymeric layer,

(f) developing the exposed polymeric layer with an aqueous developer to form a patterned polymeric layer, and

(g) optionally, baking the patterned polymeric layer.

In the above process, any carrier substrate can be removed after the lamination step and before the developing step (e.g., before or after the exposing step).

In embodiments where the dry film structure is photosensitive, the polymeric layer can be exposed through a desired patterned photomask. Examples of active energy beams used for exposure include electron beams, ultraviolet light and X-ray, with ultraviolet light being preferable. As a light source, it is possible to use a low-pressure mercury lamp, high-pressure mercury lamp, extra-high-pressure mercury lamp, halogen lamp, etc. The exposure dose is typically from about 100 mJ/cm² to about 1,000 mJ/cm².

The carrier substrate can be removed by peeling before or after the exposure.

After the exposure, the polymeric layer can be heat treated to at least about 80° C. (e.g., at least about 85° C., at least about 90° C., at least about 95° C., or at least about 100° C.) to at most about 135° C. (e.g., at most about 130° C., at most about 125° C., at most about 120° C., or at most about 110° C.) for at least about 60 seconds (e.g., at least about 65 seconds, or at least about 70 seconds) to at most about 90 seconds (e.g., at most about 85 minutes, or at most about 80 seconds). The heat treatment is usually accomplished by use of a hot plate or oven.

After post exposure bake, the polymeric layer can be developed to remove exposed portions. Development can be carried out by, for example, an immersion method or a spraying method. Microholes and fine lines can be generated in the polymeric layer on the laminated substrate after development.

As a developer, basic alkali aqueous solution can be used. Examples of the basic compounds that can be used to prepare a developer include hydroxides or carbonates of alkali metals, alkaline earth metals, or ammonium ion, and amine compounds. More specifically, examples of basic compounds include: 2-dimethylaminoethanol, 3-dimethylamino-1-propanol, 4-dimethylamino-1-butanol, 5-dimethylamino-1-pentanol, 6-dimethylamino-1-hexanol, 2-dimethylamino-2-methyl-1-propanol, 3-dimethylamino-2,2-dimethyl-1-propanol, 2-diethylaminosthanol, 3-diethylamino-1-propanol, 2-diisopropylaminoethanol, 2-di-n-butylaminoethanol, N,N-dibenzyl-2-aminoethanol, 2-(2-dimethylaminoethoxy)ethanol, 2-(2-diethylaminoethoxy)ethanol, 1-dimethylamino-2-propanol, 1-diethylamino-2-propanol, N-methyldiethanolamine, N-ethyldiethanolamine, N-n-butyldiethanolamine, N-t-butyldiethanolamine, N-lauryldiethanolamine, 3-diethylamino-1,2-propa nediol, triethanolamine, triisopropanolamine, N-methylethanolamine, N-ethylethanolamine, N-n-butylethanolamine, N-t-butylethanolamine, diethanolamine, diisopropanolamine, 2-aminoethanol, 3-amino-1-propanol, 4-amino-1-butanol, 6-amino-1-hexanol, 1-amino-2-propanol, 2-amino-2,2-dimethyl-1-propanol, 1-aminobutanol, 2-amino-1-butanol, N-(2-aminoethyl)ethanolamine, 2-amino-2-methyl-1,3-propanediol, 2-amino-2-ethyl-1,3-propanediol, 3-amino-1,2-propanediol, 2-amino-2-hydroxymethyl-1,3-propanediol, sodium hydroxide, potassium hydroxide, ammonium hydroxide, sodium carbonate, potassium carbonate, ammonium carbonate, sodium hydrogen carbonate, potassium hydrogen carbonate, ammonium hydrogen carbonate, tetramethylammonium hydroxide, tetraethylammonium hydroxide, tetrapropylammonium hydroxide, tetraisopropylammonium hydroxide, aminomethanol, 2-aminoethanol, 3-aminopropanol, 2-aminopropanol, methylamine, ethylamine, propylamine, isopropylamine, dimethylamine, diethylamine, dipropylamine, diisopropylamine, trimethylamine, triethylamine, tripropylamine, or triisopropylamine. Any other basic compound can also be used as long as it is soluble in water or alcohol and a solution thereof exhibits basicity.

The most preferred basic alkali aqueous developers are dilute aqueous solutions of sodium hydroxide, tetramethylammonium hydroxide (TMAH), or sodium carbonate. After the development, the polymeric layer can generally be rinsed with water to remove any remaining developer. Before water rinsing, developer components may be removed by rinsing with a dilute acidic aqueous solution.

After the development and water washing, the patterned polymeric layer can be heat treated to at least about 50° C. (e.g., at least about 60° C., at least about 70° C., at least about 80° C., or at least about 90° C.) to at most about 150° C. (e.g., at most about 140° C., at most about 130° C., at most about 120° C., or at most about 110° C.) for at least about 30 seconds (e.g., at least about 1 minute, or at least about 2 minutes) to at most about 5 minutes (e.g., at most about 4 minutes, or at most about 3 minutes). The heat treatment is usually accomplished by use of a hot plate or oven.

In some embodiments, the polybenzoxazole precursor polymer in the polymeric lay can be cured and converted to polybenzoxazole after the development and water washing. The patterned polymeric layer can be cured by heating from at least about 200° C. (e.g., at least about 220° C., at least about 240° C., at least about 260° C., or at least about 275° C.). to at most about 350° C. (e.g., at most about 335° C., at most about 320° C., at most about 300° C., or at most about 280° C.) for at least about 30 minutes (e.g., at least about 45 minute, or at least about 1 hour) to at most about 2 hours (e.g., at most about 90 minutes, or at most about 75 minutes). The heat treatment is usually accomplished by use of a hot plate or oven.

In some embodiments, this disclosure features a process for construction of a build-up layer stack. The process includes: (a) providing a substrate (e.g., an electronic substrate) laminated with a dielectric layer; (b) removing the protective layer from the dry film structure described herein; (c) applying the polymeric layer of the structure obtained in step (b) onto the dielectric layer; (d) forming a relief pattern in the polymeric layer, the relief pattern containing open areas; (e) selectively depositing a copper layer in the open areas in the polymeric layer; and (f) removing the polymeric layer. In some embodiments, forming a relief pattern in the polymeric layer in the above process can further include: exposing the polymeric layer to actinic radiation through a mask; baking the polymeric layer; removing the carrier substrate, and developing the exposed areas of the polymeric area by an aqueous developer.

In some embodiments, the process for construction of a build-up layer stack described above can include the following steps:

(a) providing a substrate (e.g., an electronic substrate) laminated with dielectric layer (e.g., a patterned dielectric layer),

(b) removing the protective layer of a photosensitive dry film structure of this disclosure,

(c) laminating the polymeric layer of the photosensitive dry film structure to the dielectric layer to form a laminate,

(d) exposing the polymeric layer to actinic radiation through a mask,

(e) baking the exposed polymeric layer,

(f) developing the exposed areas of the polymeric layer by an aqueous developer to form open areas in the polymeric layer,

(g) selectively depositing a copper layer in open areas of the polymeric layer, and

(h) removing the polymeric layer.

In some embodiments, the dielectric layer may contain a copper seed layer, which can be uncovered after the polymeric layer is removed. In such cases, the above process can further contain step (i): removing the copper seed layer using a copper etching solution. In the above process, the carrier substrate can be removed before or after the exposure to actinic radiation.

The steps (a) to (i) describe above can be applied as many times as needed on one or both sides of the substrate.

In general, the processes described above can be used to form an article to be used in a semiconductor device. Examples of such articles include a semiconductor substrate, a flexible film for electronics, a wire isolation, a wire coating, a wire enamel, or an inked substrate. Examples of semiconductor devices that can be made from such articles include an integrated circuit, a light emitting diode, a solar cell, and a transistor.

Some embodiments of this disclosure concerns positive tone photosensitive compositions containing: 1) at least one blocked polybenzoxazole precursor polymer; 2) at least one oxime compound containing a phenyl ring substituted with an oxime group and a hydroxy group at the o-position relative to the oxime group; 3) at least one photosensitive compound; and 4) at least one solvent.

The blocked (protected) polybenzoxazole precursor polymer can be selected from the group consisting of polymers with Structures (III-a), (III-b), (IV-a), (IV-b) and (IV-c) as described earlier. In some embodiments, the oxime compound containing a phenyl ring substituted with an oxime group and a hydroxy group at the o-position relative to the oxime group has Structure (VII):

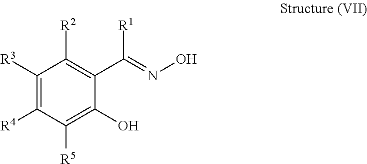

in which R¹, R², R³, R⁴ and R⁵ defined earlier. Examples of suitable compounds of Structure (VII) are shown earlier.

In some embodiments, the positive tone photosensitive compositions can further include other additives, such as quenchers, adhesion promoters, particles, plasticizers, surfactants, etc. Such additives have been described earlier in other embodiments.

The following examples are provided to illustrate the principles and practice of the present disclosure more clearly. It should be understood that the present disclosure is not limited to the examples described.

### Synthesis Example 1

### Synthesis of Polybenzoxazole Precursor Polymer (P-I)

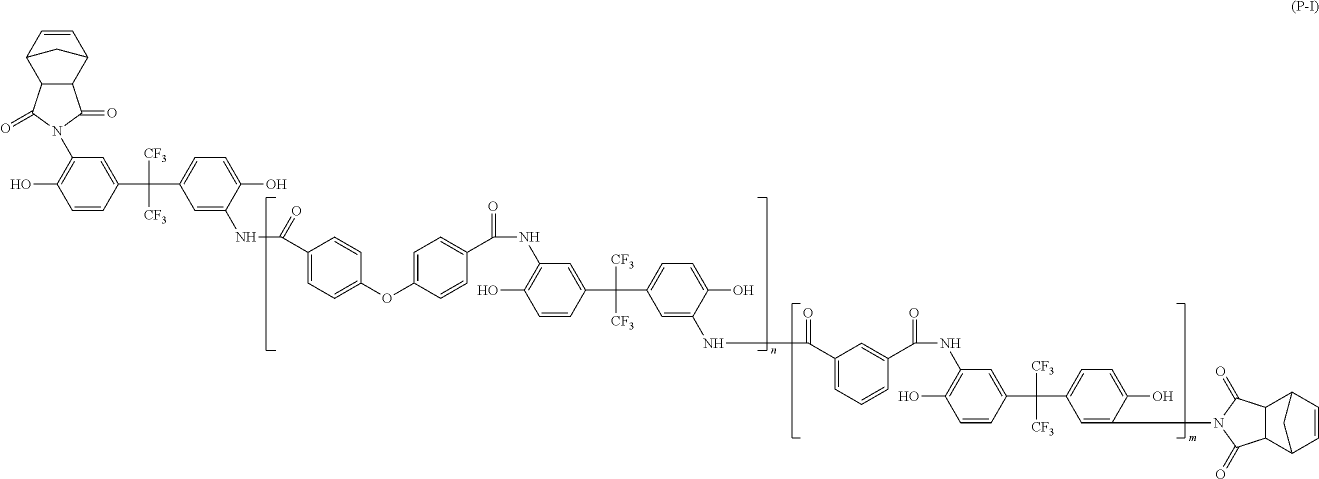

To a 2 L, three-necked, round bottom flask equipped with a mechanical stirrer, nitrogen inlet and addition funnel, 155.9 g of hexafluoro-2,2-bis(3-amino-4-hydroxyphenyl)propane, 64.3 g of pyridine, and 637.5 g of N-methylpyrrolidone (NMP) were added. The solution was stirred at room temperature until all solids were dissolved, then cooled in an ice water bath at 0-5° C. To this solution, 39.3 g of isophthaloyl chloride, and 56.9 g of 4.4′-oxydibenzoyl chloride dissolved in 427.5 g of NMP were added drop-wise. After the addition was completed, the resulting mixture was stirred at room temperature for 18 hours. Bicyclo[2.2.1]hept-5-ene-2,3-dicarboxylic anhydride (18.7 g) was added and the reaction mixture heated to 55° C. for 12 hours. The viscous solution was cooled to room temperature and precipitated in 10 liters of vigorously stirred de-ionized water. The polymer was collected by filtration and washed with de-ionized water and a water/methanol (50/50) mixture. The polymer was dried under vacuum conditions at 105° C. for 24 hours. The yield was almost quantitative and the inherent viscosity (iv) of the polymer was 0.20 dl/g measured in NMP at a concentration of 0.5 g/dl at 25° C. The polymer thus obtained had a weight average molecular weight about 18,000 Daltons.

### Synthesis Example 2

### Synthesis of Protected (Blocked) Polybenzoxazole Precursor Polymer (P-II)

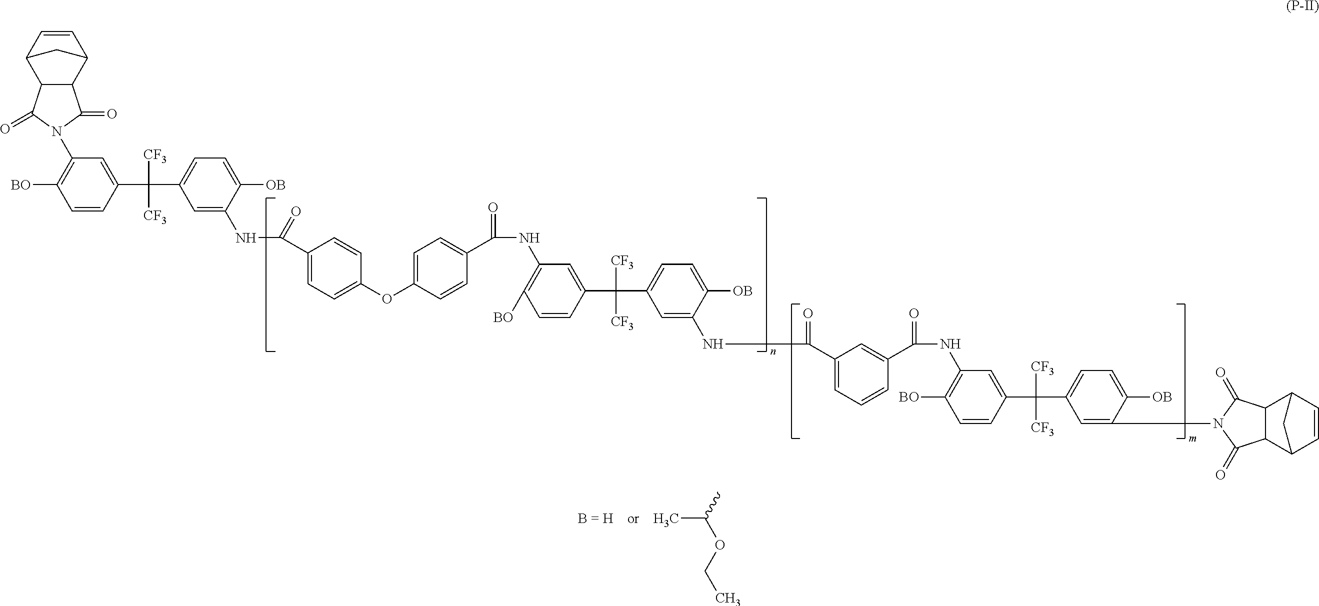

To a 1 L three-necked round bottom flask equipped with a mechanical stirrer, 100 g of the polymer obtained in Synthesis Example 1 and 300 g of PGMEA were added. To this solution was added 2 wt % para-toluenesulfonic acid (pTSA) in PGMEA (11.7 g), followed by 10.0 g of ethyl vinyl ether. The solution was stirred for one hour. To this reaction solution was added 25.0 g of a 1 wt % triethylamine in PGMEA solution. After stirring for one hour, the reaction mixture was diluted with a mixture of PGMEA, acetone and hexane and washed thrice with deionized water. The washed polymer solution was distilled under vacuum to remove acetone, hexane and residual water. The distilled polymer solution was used in the following examples without further purification. The yield was quantitative, the solids content was 46.35%, and the blocking level was 28%. The polymer had a weight average molecular weight about 20,000 Daltons.

### Composition Example 1

### Formulation of Polymer Solution for Preparation of Polymeric Layer of First Dry Film Structure (F-1)

373.2 parts of the polymer solution obtained in Synthesis Example 2, 7.47 parts of 5-nonyl-2-hydroxybenzaldoxime, 43.64 part of GBL, 136.49 g of propylene glycol monomethyl ether acetate (PGMEA), 1.92 parts of 2-{2-[2-(2,6-dimethoxyphenoxy)ethoxy]ethoxy}-N,N-bis(2-methoxyethyl)ethanamine and 3.83 parts of 3(2H)-benzofuranone, O-[(4-methylphenyl)sulfonyl]oxime were mixed for 24 hours. This formulation was then filtered by using a 1.0 μm filter (Ultradyne from Meissner Filtration Product, Inc., cat. no. CFTM1.0-44B1).

### Composition Example 2

### Formulation of Polymer Solution for Preparation of Polymeric Layer of Second Dry Film Structure (F-2)

1381.4 parts of the polymer solution obtained in Synthesis Example 2, 27.63 parts of 5-nonyl-2-hydroxybenzaldoxime, 161.52 part of GBL, 505.00 g of propylene glycol monomethyl ether acetate (PGMEA), 22.74 parts of (3-glycidyloxypropyl)trimethoxy silane, 7.12 parts of 2-{2-[2-(2,6-dimethoxyphenoxy)ethoxy]ethoxy}-N,N-bis(2-methoxyethyl)ethanamine and 14.16 parts of 3(2H)-benzofuranone, O-[(4-methylphenyl)sulfonyl]oxime were mixed for 36 hours. This formulation was then filtered by using a 0.2 μm filter (Ultradyne from Meissner Filtration Product, Inc., cat. no. CFTM10.2-44B1).

### Dry Film Structures (Examples DF-1 to DF-14)

Dry film structures containing a carrier substrate, a polymeric layer, and a protective layer were prepared as follows. A filtered photosensitive polymer solution (F-1 or F-2) was applied via slot-die coater from Frontier Industrial Technologies (Towanda, Pa.) with a line speed of 5 feet/minutes (150 cm per minutes) onto a polyethylene terephthalate film (PET) TA 30 (manufactured by Toray Plastics America, Inc.) having a thickness of 36 μm (which was used as a carrier substrate with or without online corona treatment) and dried at 80-95° C. to obtain a polymeric layer with thicknesses of approximately 4.0 microns to 10.0 microns. The lamination pressure was 30 psi and the vacuum was 0.7 Torr. On this polymeric layer, a biaxially oriented polypropylene films (BOPP) (manufactured by IMPEX GLOBAL LLC, trade name 80ga BOPP) was laminated by a roll compression to act as a protective layer. Table 1 summarizes the details of these experiments.

TABLE 1

| | | | | | Polymeric | |
|---|---|---|---|---|---|---|
| Exam- | Com- | pump | | oven | layer | |
| ple | posi- | speed | Corona | temp | thickness | |
| # | tion | (RPM) | Treatment | (° C.) | (μm) | PET Film |
| DF-1 | F-1 | 8.9 | 0.94 | 93.5 | 9 | 1.41 mil film |
| | | | | | | TA30 |
| DF-2 | F1 | 9.9 | 0.94 | 93.5 | 10 | 1.41 mil film |
| | | | | | | TA30 |
| DF-3 | F1 | 5 | 0.94 | 93.5 | 5 | 1.41 mil film |
| | | | | | | TA30 |
| DF-4 | F-2 | 12.5 | 0 | 93.5 | 8.5 | 1.41 mil film |
| | | | | | | TA30 |
| DF-5 | F-2 | 12.5 | 0.1 | 93.5 | 8.5 | 1.41 mil film |
| | | | | | | TA30 |
| DF-6 | F-2 | 12.5 | 0.5 | 93.5 | 8.5 | 1.41 mil film |
| | | | | | | TA30 |
| DF-7 | F-2 | 12.5 | 0 | 93.5 | 8.5 | 3 mil Melinex |
| DF-8 | F-2 | 12.5 | 0.5 | 93.5 | 8.5 | 3 mil Melinex |
| DF-9 | F-2 | 12.5 | 0 | 82.2 | 8.5 | 3 mil Melinex |
| DF-10 | F-2 | 12.5 | 0.5 | 82.2 | 8.5 | 3 mil Melinex |
| DF-11 | F-2 | 16.3 | 0 | 82.2 | 8.5 | 1.41 mil film |
| | | | | | | TA30 |
| DF-12 | F-2 | 13.6 | 0.1 | 82.2 | 10 | 1.41 mil film |
| | | | | | | TA30 |
| DF-13 | F-2 | 20.4 | 0.5 | 82.2 | 10 | 1.41 mil film |
| | | | | | | TA30 |
| DF-14 | F-2 | 13.87 | 0 | 82.2 | 7.4 | 1.41 mil film |
| | | | | | | TA30 |

### Lamination of Dry Film Structures (Examples L-1 to L-3)

After the removal of the protective layer by peeling, the polymeric layer of the dry film structure (6″×6″) was placed in contact with a 4″ Wafernet copper coated wafer (a substrate). The polymeric layer was laminated onto the Cu coated wafer by vacuum lamination at 90-110° C., followed by being subjected to a pressure of 30 psi. The total time was 180 seconds. Lamination process was done by using a DPL-24A Differential Pressure Laminator manufactured by OPTEK, NJ. The results of the lamination are summarized in Table 2.

TABLE 2

| | | | Temperature | Time | Pressure | Vacuum | |
|---|---|---|---|---|---|---|---|
| Example # | Film | Wafer | (° C.) | (sec) | (psi) | (Torr) | Observation |
| L-1 | DF-1 | Cu | 90 | 180 | 30 | 0.68-0.74 | laminated |
| | | | | | | | well |
| L-2 | DF-1 | Cu | 100 | 180 | 30 | 0.68-0.74 | laminated |
| | | | | | | | well |
| L-3 | DF-14 | Cu | 90 | 300 | 30 | 0.68-0.75 | laminated |
| | | | | | | | well |

### Lithographic Evaluation of Laminated DF-14

The carrier substrate of the copper coated wafer laminated by composition DF-14 in Example L-3 was removed. The photosensitive polymeric layer was then exposed to actinic light utilizing an i-line stepper in a patterned exposure array, which incrementally increased exposure energy 100 mJ/cm² with a starting exposure energy of 100 mJ/cm². The exposed polymeric layer was then heated at 135° C. for 90 seconds, and developed using two 60-second puddles with a 2.38% aqueous TMAH. A relief pattern with a resolution of 6 microns was obtained at energy dose of 300 mJ/cm². The final film thickness was 6.66 μm and film thickness loss was 9.9%.

### Composition Example 3

### Formulation of a Polymer Solution for Preparation of Polymeric Layer of Dry Film Structure (F-3)

100 parts of the polymer solution obtained in Synthesis Example 2, 25 parts of GBL and 25 parts of cyclopentanone are mixed for 24 hours. This formulation is then filtered by using a 1.0 μm filter (Ultradyne from Meissner Filtration Product, Inc., cat. no. CFTM1.0-44B1).

### Composition Example 4

### Formulation of a Polymer Solution for Preparation of Polymeric Layer of Dry Film Structure (F-4)

100 parts of the polymer solution obtained in Synthesis Example 2, 50 parts of GBL and 2 parts of PAG of Structure (V-f) are mixed for 24 hours. This formulation is then filtered by using a 1.0 μm filter (Ultradyne from Meissner Filtration Product, Inc., cat. no. CFTM1.0-44B1).

### Composition Example 5

### Formulation of a Polymer Solution for Preparation of Polymeric Layer of Dry Film Structure (F-5)

100 parts of the polymer solution obtained in Synthesis Example 2, 10 parts of GBL, 40 parts of PGME and 3 parts of (5-propylsulfonyloxyimino-5H-thiophen-2-ylidene)-2-methylphenyl-acetonitrile as a PAG are mixed for 24 hours. This formulation is then filtered by using a 1.0 μm filter (Ultradyne from Meissner Filtration Product, Inc., cat. no. CFTM1.0-44B1).

### Composition Example 6

### Formulation of a Polymer Solution for Preparation of Polymeric Layer of Dry Film Structure (F-6)

100 parts of the polymer solution obtained in Synthesis Example 2, 50 parts of PGMEA, 4 parts of (5-propylsulfonyloxyimino-5H-thiophen-2-ylidene)-2-methylphenyl-acetonitrile as a PAG and 3 parts of salicylaldoxime are mixed for 24 hours. This formulation is then filtered by using a 1.0 μm filter (Ultradyne from Meissner Filtration Product, Inc., cat. no. CFTM1.0-44B1).

### Dry Film Structures (Examples DF-15 to DF-21)

Dry film structures containing a carrier substrate, a polymeric layer, and a protective layer are prepared as follows. Filtered solutions of compositions F-3 to F-6 are each applied via slot-die coater from Frontier Industrial Technologies (Towanda, Pa.) with a line speed of 7 feet/minutes (210 cm per minutes) onto a polyethylene terephthalate film (PET) TA 30 (manufactured by Toray Plastics America, Inc.) having a thickness of 36 μm and are dried at 80-95° C. to obtain a polymeric layer with thicknesses of approximately 4.0 microns to 10.0 microns. On the polymeric layer, a biaxially oriented polypropylene films (BOPP) (manufactured by IMPEX GLOBAL LLC, trade name 80ga BOPP) is laminated by a roll compression to act as a protection layer. Table 3 summarizes the details of these experiments.

TABLE 3

| | | | | | Polymeric | |
|---|---|---|---|---|---|---|
| | Com- | pump | | oven | layer | |
| Example | posi- | speed | Corona | temp | thickness | |
| # | tion | (RPM) | Treatment | (° F.) | (μm) | PET Film |
| DF-15 | F-3 | 8.9 | 0.94 | 94 | 9 | 1.41 mil film |
| | | | | | | TA30 |
| DF-16 | F-3 | 5 | 0 | 95 | 5 | 1.41 mil film |
| | | | | | | TA30 |
| DF-17 | F-4 | 5 | 0.94 | 90 | 5 | 1.41 mil film |
| | | | | | | TA30 |
| DF-18 | F-4 | 12.5 | 0 | 88 | 8.5 | 1.41 mil film |
| | | | | | | TA30 |
| DF-19 | F-5 | 5 | 0.1 | 83 | 5 | 1.41 mil film |
| | | | | | | TA30 |
| DF-20 | F-5 | 12.5 | 0.5 | 92 | 8.5 | 1.41 mil film |
| | | | | | | TA30 |
| DF-21 | F-6 | 12.5 | 0.5 | 92 | 8.5 | 1.41 mil film |
| | | | | | | TA31 |

### Synthesis Example 3

### Synthesis of Polybenzoxazole Precursor Polymer (P-3)

To a 4 L, three-necked, round bottom flask equipped with a mechanical stirrer, nitrogen inlet and addition funnel, 280.8 g of hexafluoro-2,2-bis(3-amino-4-hydroxyphenyl)propane, 17.02 g of 4,4′-oxydianiline, 128.6 g of pyridine, and 1280.0 g of N-methylpyrrolidone (NMP) are added. The solution is stirred at room temperature until all solids are dissolved, then cooled in an ice water bath at 0-5° C. To this solution, 93.38 g of para-phthaloyl chloride, and 84.19 g of adipoyl chloride dissolved in 860 g of NMP is added drop-wise. After the addition is completed, the resulting mixture is stirred at room temperature for 18 hours. 2-Hydroxyethylmethacrylate (8.92 g) is added and the reaction mixture is heated to 60° C. for 12 hours. The viscous solution is cooled to room temperature and precipitated in 20 liters of vigorously stirred de-ionized water. The polymer is collected by filtration and washed with de-ionized water and a water/methanol (50/50) mixture. The polymer is dried under vacuum conditions at 105° C. for 24 hours.

### Synthesis Example 4

### Synthesis of Protected (Blocked) Polybenzoxazole Precursor Polymer (P-4)

To a 2 L three-necked round bottom flask equipped with a mechanical stirrer, 200 g of the polymer obtained in Synthesis Example 3 (P-3) and 650 g of PGMEA are added. To this solution is added 2.1 wt % para-toluenesulfonic acid (pTSA) in PGMEA (24.0 g), followed by 29.2 g of t-butyl vinyl ether. The solution is stirred for one hour. To this reaction solution is added 52.0 g of a 1 wt % triethylamine in PGMEA solution. After stirring for one hour, the reaction mixture is diluted with a mixture of PGMEA, acetone and hexane and washed thrice with deionized water. The washed polymer solution is distilled under vacuum to remove acetone, hexane and residual water. The distilled polymer solution is used in the following examples without further purification.

### Composition Example 7

### Formulation of Polymer Solution for Preparation of Polymeric Layer of Dry Film Structure (F-7)

200 parts of the polymer solution obtained in Synthesis Example 4, 3.5 parts of 5-dodecyl-2-hydroxybenzaldoxime, 20 parts of GBL, 60.00 parts of propylene glycol monomethyl ether acetate (PGMEA), 2.80 parts of 3-methacryloxypropyltrimethoxysilane, 0.7 parts of 2-{2-[2-(2,6-dimethoxyphenoxy)ethoxy]ethoxy}-N,N-bis(2-methoxyethyl)ethanamine, 1.25 parts of photo acid generator of Structure (V-c) and 1.25 parts of photo acid generator of Structure (V-e) are mixed for 36 hours. This formulation is then filtered by using a 0.2 μm filter (Ultradyne from Meissner Filtration Product, Inc., cat. no. CFTM10.2-44B1).

### Dry Film Structures (Examples DF-22 to DF-24)

Dry film structures containing a carrier substrate, a polymeric layer, and a protective layer are prepared as follows. Filtered solution of composition F-7 is applied via slot-die coater from Frontier Industrial Technologies (Towanda, Pa.) with a line speed of 7 feet/minutes (210 cm per minutes) onto a polyethylene terephthalate film (PET) TA 30 (manufactured by Toray Plastics America, Inc.) having a thickness of 36 μm and are dried at 80-95° C. to obtain a polymeric layer with thicknesses of approximately 4.0 microns to 10.0 microns. On the polymeric layer, a biaxially oriented polypropylene films (BOPP) (manufactured by IMPEX GLOBAL LLC, trade name 80ga BOPP) is laminated by a roll compression to act as a protection layer. Table 4 summarizes the details of these experiments.

TABLE 4

| | | pump | | | |
|---|---|---|---|---|---|
| | | speed | Corona | oven temp | |
| Example # | Composition | (RPM) | Treatment | (° F.) | PET Film |
| DF-22 | F-7 | 9.3 | 0.94 | 95 | 1.41 mil film |
| | | | | | TA30 |
| DF-23 | F-7 | 5 | 0 | 95 | 1.41 mil film |
| | | | | | TA30 |
| DF-24 | F-7 | 5 | 0.94 | 90 | 1.41 mil film |
| | | | | | TA30 |

### Lamination of Dry Film Structure (Examples L-4 and L5)

The general procedure for preparing laminates L-4 and L-5 is the same as described for laminates L1-L3. The process conditions are shown in Table 5 below.

TABLE 5

| | | | Tem- | | | | |
|---|---|---|---|---|---|---|---|
| Exam- | | | pera- | | Pres- | | |
| ple | | | ture | Time | sure | Vacuum | Observa- |
| # | Film | Wafer | (° C.) | (sec) | (psi) | (Torr) | tion |
| L-4 | DF-22 | Cu | 90 | 180 | 30 | 0.68-0.74 | laminated |
| | | | | | | | well |
| L-5 | DF-23 | Cu | 100 | 180 | 30 | 0.68-0.74 | laminated |
| | | | | | | | well |

### Lithographic Evaluation of Laminated DF-22

The carrier substrate of the copper coated wafer laminated by DF-22 in Example L-4 is removed. The photosensitive polymeric layer is then exposed to actinic light utilizing an i-line stepper in a patterned exposure array, which incrementally increases exposure energy by 25 mJ/cm² with a starting exposure energy of 100 mJ/cm². The exposed polymeric layer is then heated at 130° C. for 120 seconds, and developed using two 60-second puddles with a 2.38% aqueous TMAH.

### Composition Example 8

### Formulation of Polymer Solution for Preparation of Polymeric Layer of Dry Film Structure (F-8)

200 parts of the polymer solution obtained in Synthesis Example 3, 4.2 parts of photo acid generator PAG-A shown below, 25 part of GBL, 45.00 parts of propylene glycol monomethyl ether (PGME), 20 parts of ethyl lactate, 7 parts of tripropylene glycol, 2.0 parts of (methylcarbamato)methyl]dimethoxy-methylsilane, and 0.2 parts of N,N-dimethylcyclohexylamine are mixed for 36 hours. This formulation is then filtered by using a 0.2 μm filter (Ultradyne from Meissner Filtration Product, Inc., cat. no. CFTM10.2-44B1).

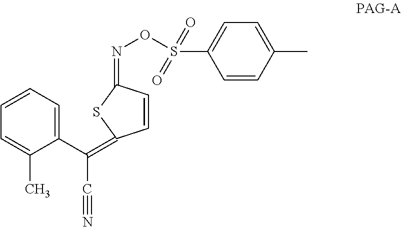 [SMILES: Cc1ccc(S(=O)(=O)O/N=C2C=C/C(=C(\C#N)c3ccccc3C)S\2)cc1]

### Dry Film Structures (Examples DF-25 to DF-27)

Dry film structures containing a carrier substrate, a polymeric layer, and a protective layer are prepared as follows. Filtered solution of composition F-8 is applied via slot-die coater from Frontier Industrial Technologies (Towanda, Pa.) with a line speed of 7 feet/minutes (210 cm per minutes) onto a polyethylene terephthalate film (PET) TA 30 (manufactured by Toray Plastics America, Inc.) having a thickness of 36 μm and are dried at 80-95° C. to obtain a polymeric layer with thicknesses of approximately 4.0 microns to 10.0 microns. On the polymeric layer, a biaxially oriented polypropylene films (BOPP) (manufactured by IMPEX GLOBAL LLC, trade name 80ga BOPP) is laminated by a roll compression to act as a protection layer. Table 6 summarizes the conditions of these experiments.

TABLE 6

| | | pump | | | |
|---|---|---|---|---|---|
| | | speed | Corona | oven temp | |
| Example # | Composition | (RPM) | Treatment | (° F.) | PET Film |
| DF-25 | F-8 | 9.5 | 0.94 | 95 | 1.41 mil film |
| | | | | | TA30 |
| DF-26 | F-8 | 6 | 0 | 90 | 1.41 mil film |
| | | | | | TA30 |
| DF-27 | F-8 | 56 | 0.94 | 90 | 1.41 mil film |
| | | | | | TA30 |

### Lamination of Dry Film Structure Examples (L-6 and L7)

The general procedure for preparing laminates L-6 and L-7 is the same as described for laminates L1-L3. The process conditions are shown in Table 7 below.

TABLE 7

| | | | Tem- | | | | |
|---|---|---|---|---|---|---|---|
| Exam- | | | pera- | | Pres- | | |
| ple | | | ture | Time | sure | Vacuum | Observa- |
| # | Film | Wafer | (° C.) | (sec) | (psi) | (Torr) | tion |
| L-6 | DF-25 | Si | 85 | 210 | 30 | 0.68-0.74 | laminates |
| | | | | | | | well |
| L-7 | DF-26 | Si | 95 | 210 | 30 | 0.68-0.74 | laminates |
| | | | | | | | well |

### Lithographic Evaluation of Laminated DF-25 (L-6)

The carrier substrate of the copper coated wafer laminated by DF-25 in Example L-6 is removed. The photosensitive polymeric layer is then exposed to actinic light utilizing an i-line stepper in a patterned exposure array, which incrementally increases exposure energy by 25 mJ/cm² with a starting exposure energy of 100 mJ/cm². The exposed polymeric layer is then heated at 130° C. for 120 seconds, and developed using two 60-second puddles with a 2.38% aqueous TMAH.

### Synthesis Example 5

### Synthesis of Polybenzoxazole Precursor Polymer (P-5)

To a 4 L, three-necked, round bottom flask equipped with a mechanical stirrer, nitrogen inlet and addition funnel, 280.8 g of hexafluoro-2,2-bis(3-amino-4-hydroxyphenyl)propane, 17.02 g of 4,4′-oxydianiline, 128.6 g of pyridine, and 1280.0 g of N-methylpyrrolidone (NMP) are added. The solution is stirred at room temperature until all solids are dissolved, then cooled in an ice water bath at 0-5° C. To this solution, 93.38 g of iso-phthaloyl chloride, and 83.5 g of 1,4-cyclohexanedicarbonyldichloride dissolved in 900 g of NMP are added drop-wise. After the addition is completed, the resulting mixture is stirred at room temperature for 18 hours.

### Synthesis Example 6

### Synthesis of Protected (Blocked) Polybenzoxazole Precursor Polymer (P-6)

To a 2 L three-necked round bottom flask equipped with a mechanical stirrer, 200 g of the polymer obtained in Synthesis Example 5 (P-5) and 650 g of PGMEA are added. To this solution is added 22 g of sodium bicarbonate followed by 50.0 of di-t-butyl dicarbonate. After stirring for one hour, the reaction mixture is added to 10 liters of deionized water. The precipitated product is collected by filtration, washed with 2 liters more deionized water. The final polymer is dried at 40° C. inside a vacuum oven for 48 hours.

### Composition Example 9

### Formulation of Polymer Solution for Preparation of Polymeric Layer of Dry Film Structure (F-9)

100 parts of the polymer obtained in Synthesis Example 6, 5.0 parts of photo acid generator PAG-B shown below, 125 part of GBL, 25.00 parts of propylene glycol monomethyl ether (PGME), 25 parts of propylene glycol methyl ether acetate (PGMEA), 25 parts of tetrahydrofurfuryl alcohol, 7 parts of dipropylene glycol, 4.0 parts of methacryloxyethoxy trimethyl silane, and 0.25 parts of diazabicyclo[5.4.0]undec-7-ene (DBU) are mixed for 36 hours. This formulation is then filtered by using a 0.2 μm filter (Ultradyne from Meissner Filtration Product, Inc., cat. no. CFTM10.2-44B1).

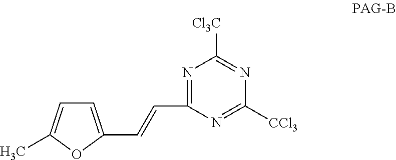

### Dry Film Structure (Example DF-28)

The procedure for preparing dry film structure DF-28 is the same as dry film structure of DF-27 except composition of DF-9 is used.

### Lamination of Dry Film Structure (Example L-8)

The general procedure for preparing laminate L-8 is the same as described for laminate L-6. The process conditions are shown in Table 8 below.

TABLE 8

| | | | Tem- | | | | |
|---|---|---|---|---|---|---|---|
| Exam- | | | pera- | | Pres- | | |
| ple | | | ture | Time | sure | Vacuum | Observa- |
| # | Film | Wafer | (° C.) | (sec) | (psi) | (Torr) | tion |
| L-8 | DF-28 | Si | 85 | 210 | 30 | 0.68-0.74 | laminates |
| | | | | | | | well |

### Synthesis Example 7

### Synthesis of Polybenzoxazole Precursor Polymer (P-7)

To a 2 L, three-necked, round bottom flask equipped with a mechanical stirrer, nitrogen inlet and addition funnel, 155.9 g of hexafluoro-2,2-bis(3-amino-4-hydroxyphenyl)propane, 64.3 g of pyridine, and 637.5 g of N-methylpyrrolidone (NMP) are added. The solution is stirred at room temperature until all solids were dissolved, then cooled in an ice water bath at 0-5° C. To this solution, 39.3 g of isophthaloyl chloride and 56.9 g of 4.4′-oxydibenzoyl chloride dissolved in 427.5 g of NMP are added dropwise. After the addition is completed, the resulting mixture is stirred at room temperature for 18 hours.

### Synthesis Example 8

### Synthesis of Protected (Blocked) Polybenzoxazole Precursor Polymer (P-8)

To a 1 L three-necked round bottom flask equipped with a mechanical stirrer, 100 g of the polymer obtained in Synthesis Example 7 and 300 g of PGMEA are added. To this solution is added 20.0 g of tert-butyl(chloro)dimethylsilane and 9.0 g of imidazole. After stirring for two hour, the reaction mixture is diluted with a mixture of PGMEA, acetone and hexane, and washed thrice with deionized water. The washed polymer solution is distilled under vacuum to remove acetone, hexane and residual water. The distilled polymer solution is used in the following examples without further purification.

### Dry Film Structure (Example DF-29)

The procedure for preparing dry film structure DF-29 is the same as dry film structures of DF-27 and DF-28 except the polymer solution of Synthesis Example 8 is used as the polymeric solution.

### Lamination of Dry Film Structure (Example L-9)

The general procedure for preparing laminate L-9 is the same as laminate L-8. The process conditions are shown in Table 9 below.

TABLE 9

| | | | Tem- | | | | |
|---|---|---|---|---|---|---|---|
| Exam- | | | pera- | | Pres- | | |
| ple | | | ture | Time | sure | Vacuum | Observa- |
| # | Film | Wafer | (° C.) | (sec) | (psi) | (Torr) | tion |
| L-9 | DF-29 | Si | 85 | 210 | 30 | 0.68-0.74 | laminated |
| | | | | | | | well |

1. A dry film structure, comprising:
a carrier substrate;
a protective layer; and
a polymeric layer between the carrier substrate and the protective layer, the polymeric layer comprising at least one blocked polybenzoxazole precursor polymer.

2. The dry film structure of claim 1, wherein the polymeric layer is photosensitive.

3. The dry film structure of claim 1, wherein the blocked polybenzoxazole precursor polymer comprises a polymer of Structure (III-a), (III-b), (IV-a), (IV-b), or (IV-c): 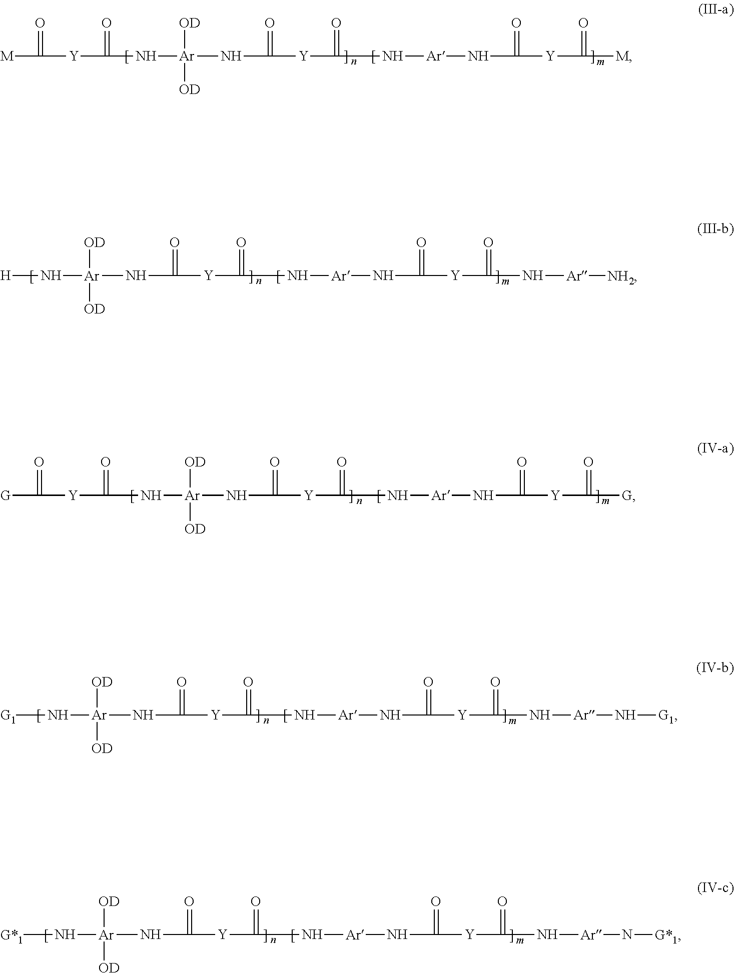
wherein
n is an integer from 2 to 1000;
m is an integer from 0 to 500,
Ar is a tetravalent aromatic group, a tetravalent heterocyclic group, or a mixture thereof;
Ar′ is a divalent aromatic group, a divalent aliphatic group, a divalent alicyclic group, a divalent heterocyclic group, or a mixture thereof;
Ar″ is Ar(OD)₂ or Ar′;
Y is a divalent aromatic group, a divalent aliphatic group, a divalent heterocyclic group, or a mixture thereof;
M is halogen or an —OR group wherein R is H or C₁-C₄ linear or branched alkyl group;
G is a monovalent moiety containing at least one carbon-carbon multiple bond;
G₁ is a monovalent moiety containing at least one carbon-carbon multiple bond;
G*₁ is a divalent moiety containing at least one carbon-carbon multiple bond; and
each D, independently, is a hydrogen atom or an acid removable blocking group;
wherein the ratio of blocked phenolic hydroxyl groups to the total number of phenolic hydroxyl groups in a polymer of Structure (III-a), (III-b), (IV-a), (IV-b), or (IV-c) ranges from about 1 mole % to about 99 mole %.

4. The dry film structure of claim 1, wherein the polymeric layer further comprises at least one photoacid generator.

5. The dry film structure of claim 4, wherein the at least one photoacid generator comprises an oxime sulfonate of Structure (V) or (VI): 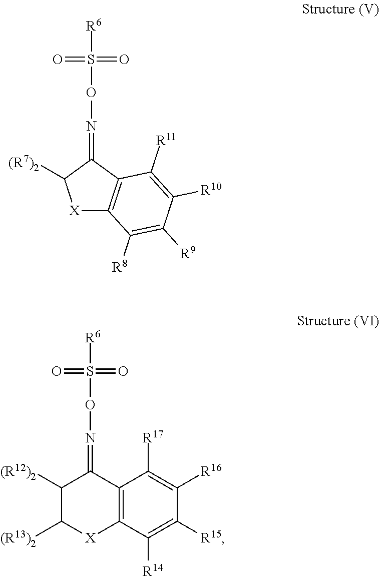
wherein
R⁶ is selected from the group consisting of substituted or unsubstituted C₁-C₁₂ linear or branched alkyl, substituted or unsubstituted C₅-C₁₀ cycloalkyl or heterocycloalkyl, and substituted or unsubstituted C₆-C₁₂ aryl or heteroaryl;
each R⁷ is independently selected from the group consisting of hydrogen, halogen, substituted or unsubstituted C₁-C₁₂ linear or branched alkyl, substituted or unsubstituted C₅-C₁₀ cycloalkyl or heterocycloalkyl, and substituted or unsubstituted C₆-C₁₂ aryl or heteroaryl;
R⁸ to R¹⁷ are each independently selected from the group consisting of hydrogen, halogen, substituted or unsubstituted C₁-C₁₂ linear or branched alkyl, substituted or unsubstituted C₅-C₁₀ cycloalkyl or heterocycloalkyl, and substituted or unsubstituted C₆-C₁₂ aryl or heteroaryl, or any two adjacent R⁸ to R¹¹, R¹² to R¹³, and R¹⁴ to R¹⁷, together with the ring carbon atoms to which they are attached, form a six-membered ring; and
X is an oxygen or sulfur atom.

6. The dry film structure of claim 1, wherein the polymeric layer further comprises at least one quencher.

7. The dry film structure of claim 6, wherein the at least one quencher comprises a tertiary amine.

8. The dry film structure of claim 7, wherein the tertiary amine is compound B-1, B-2, B3, B-4, B-5, B-6, B-7, B-8, or B-9:

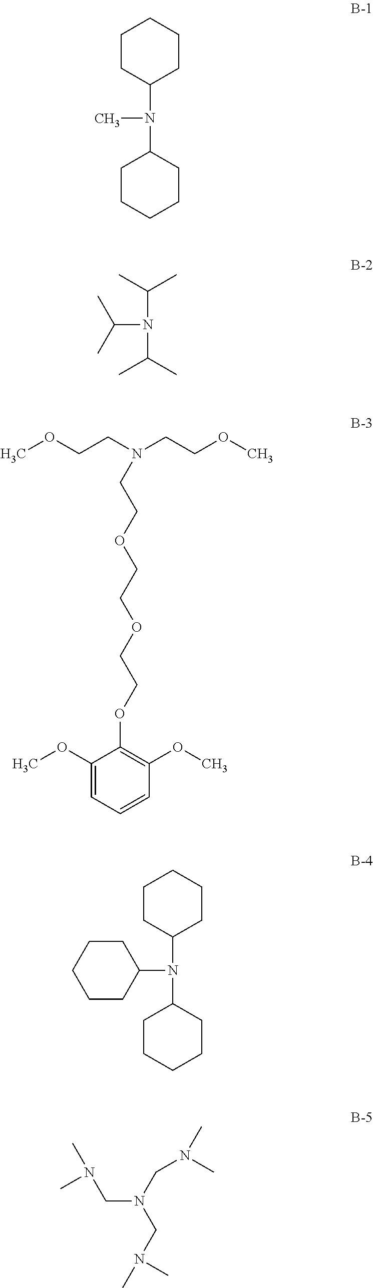

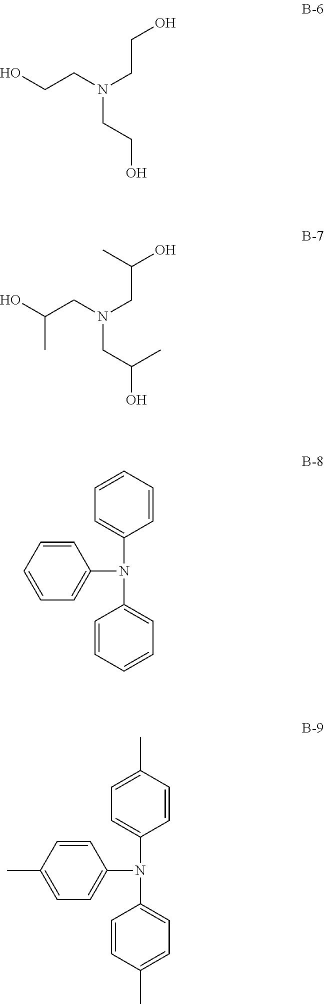

9. The dry film structure of claim 1, wherein the polymeric layer further comprises at least one adhesion promoter.

10. The dry film structure of claim 1, wherein the polymeric layer further comprises at least one copper compatibilizing additive.

11. The dry film structure of claim 10, wherein the at least one copper compatibilizing additive comprises an oxime compound Structure (VII): 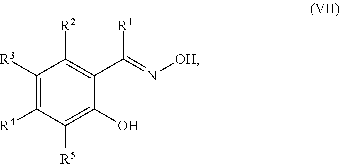
in which
R¹ is selected from the group consisting of hydrogen, substituted or unsubstituted C₁-C₁₂ linear or branched alkyl, substituted or unsubstituted C₅-C₁₀ cycloalkyl or heterocycloalkyl, and substituted or unsubstituted C₆-C₁₂ aryl or heteroaryl; and
R² to R⁵ are each independently selected from the group consisting of hydrogen, halogen, substituted or unsubstituted C₁-C₁₂ linear or branched alkyl, substituted or unsubstituted C₅-C₁₀ cycloalkyl, and substituted or unsubstituted C₆-C₁₂ aryl; or any two adjacent R² to R⁵, together with the ring carbon atoms to which they are attached, form a six-membered ring.

12. The dry film structure of claim 11, wherein the at least one copper compatibilizing additive comprises an oxime compound selected from the group consisting of

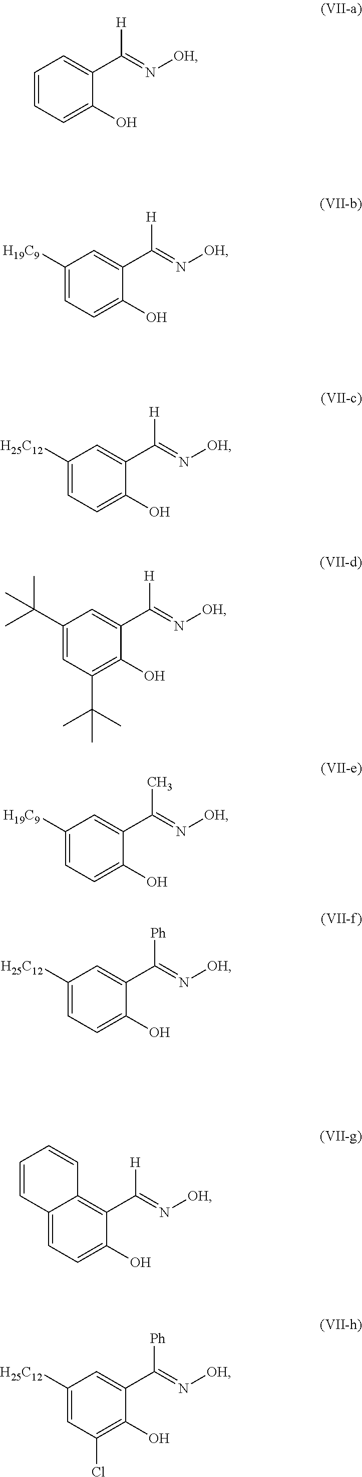

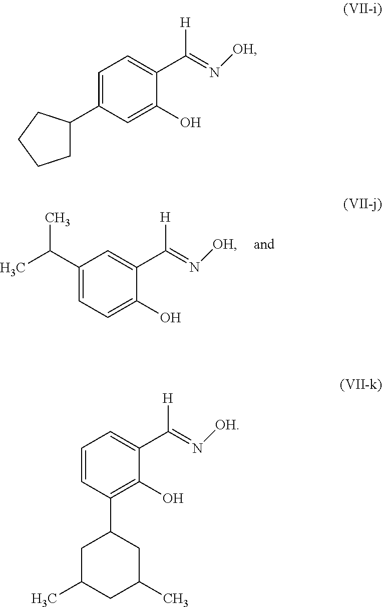 [SMILES: O/N=C/c1ccc(C2CCCC2)cc1O ; CC(C)c1ccc(O)c(/C=N/O)c1 ; CC1CC(C)CC(c2cccc(/C=N/O)c2O)C1]

13. The dry film structure of claim 1, wherein the polymeric layer further comprises at least one nanoparticle.

14. The dry film structure of claim 1, wherein the polymeric layer further comprises at least one quencher; at least one adhesion promoter; and at least one nanoparticle.

15. The dry film structure of claim 1, wherein the blocked polybenzoxazole precursor polymer has a weight average molecular weight of at least about 15,000 Daltons.

16. The dry film structure of claim 1, wherein the polymeric layer has a thickness ranging from about 2 microns to about 100 microns.

17. A process, comprising:
(a) removing the protective layer from the dry film structure of claim 1; and
(b) applying the structure obtained in step (a) onto an electronic substrate to form a laminate.

18. The process of claim 17, further comprising exposing the polymeric layer in the laminate to actinic radiation.

19. The process of claim 18, further comprising removing the carrier substrate before or after exposing the polymeric layer.

20. The process of claim 19, further comprising developing the exposed polymeric layer.

21. A process for construction of a build-up layer stack, comprising:
(a) providing a substrate laminated with a dielectric layer;
(b) removing the protective layer from the dry film structure of claim 1;
(c) applying the structure obtained in step (b) onto the dielectric layer;
(d) forming a relief pattern in the polymeric layer, the relief pattern containing open areas;
(e) selectively depositing a copper layer in the open areas in the polymeric layer; and
(f) removing the polymeric layer.

22. The process of claim 21, wherein forming a relief pattern in the polymeric layer comprises:
exposing the polymeric layer to actinic radiation through a mask;
baking the polymeric layer;
removing the carrier substrate, and
developing the exposed areas of the polymeric area by an aqueous developer.

23. An article formed by the process of claim 1, wherein the article is a semiconductor substrate, a flexible film for electronics, a wire isolation, a wire coating, a wire enamel, or an inked substrate.

24. An electronic device, comprising the article of claim 23.

25. The electronic device of claim 24, wherein the electronic device is an integrated circuit, a light emitting diode, a solar cell, or a transistor.

26. A process of forming a dry film structure, comprising:
coating a composition containing at least one blocked polybenzoxazole precursor polymer onto a carrier substrate;
drying the coated composition to form a polymeric layer; and
applying a protective layer onto the polymeric layer to form the dry film structure.
